(19) United States
(12) Patent Application Publication
(10) Pub. No.: US 2026/0005166 A1
(43) Pub. Date: Jan. 1, 2026

(54) SEMICONDUCTOR DIE PACKAGES AND METHODS OF FORMATION

(71) Applicant: Taiwan Semiconductor Manufacturing Company, Ltd., Hsinchu (TW)

(72) Inventors: Tzu Jung TIEN, Hsinchu County (TW); Jen-Yuan CHANG, Hsinchu City (TW)

(21) Appl. No.: 18/755,822

(22) Filed: Jun. 27, 2024

(51) Int. Cl. H01L 23/00; H01L 23/31; H01L 23/48; H01L 23/58; H01L 25/00; H01L 25/065

(52) U.S. Cl. CPC H01L 24/03; H01L 23/3171; H01L 23/585; H01L 24/05; H01L 24/08; H01L 25/0657; H01L 25/50; H01L 23/481; H01L 23/562; H01L 23/564; H01L 2224/035; H01L 2224/05547; H01L 2224/08146; H01L 2224/08225

(57) ABSTRACT

A recess is formed through a passivation layer of an integrated circuit (IC) die and into an opening in a metal pad structure at the top of a seal ring structure of the IC die. The recess is formed to open up any voids that may have occurred in the passivation layer within the opening in the metal pad structure. This enables the recess (and thus, the void) to be filled in, which reduces the likelihood that the void might otherwise cause delamination and film peeling in the passivation layer. The recess (and thus, the void) may be filled in to form a bonding via and a bonding pad, which may be dummy structures or may be used to bond the IC die with another IC in the semiconductor die package.

### BACKGROUND

A semiconductor die package may include a plurality of integrated circuit (IC) dies that offer a variety of functionalities. Examples of IC dies include a system-on-chip (SoC) IC die, a dynamic random access memory (DRAM) IC die, a logic IC die, and/or a high bandwidth memory (HBM) IC die, among other examples. Some semiconductor die packages include an interposer that enables IC dies to be laterally arranged on the interposer. In some semiconductor die packages, IC dies are vertically arranged using three-dimensional (3D) packaging techniques such as direct bonding.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1E are diagrams of an example of a semiconductor die package described herein.

FIGS. 2A-2I are diagrams of examples of top view layouts for seal ring structures in a semiconductor die package described herein.

FIGS. 3A-3E are diagrams of an example implementation of forming a portion of an IC die described herein.

FIGS. 4A-4G are diagrams of an example implementation of forming a portion of an IC die described herein.

FIGS. 5A-5G are diagrams of an example implementation of forming a portion of an IC die described herein.

FIGS. 6A-6H are diagrams of an example implementation of forming a portion of a semiconductor die package described herein.

FIGS. 7A-7E are diagrams of an example of a semiconductor die package described herein.

FIGS. 8A-8C are diagrams of an example implementation of forming a portion of an IC die described herein.

FIG. 9 is a flowchart of an example process associated with forming a semiconductor die package described herein.

FIG. 10 is a flowchart of an example process associated with forming a semiconductor die package described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated circuit (IC) die of a semiconductor die package may include a seal ring structure around a device layer of the IC die. The seal ring structure may include a ring of interconnected conductive structures that provide increased structural rigidity for the IC die, which may reduce a likelihood of cracking, warpage, and/or another type of physical damage that might otherwise result from physical stresses that are exerted on the IC die. Additionally and/or alternatively, the interconnected conductive structures of the seal ring structure may provide a humidity seal for the IC die, which may reduce a likelihood of humidity ingress in the IC die.

In some cases, structural defects may occur in one or more parts of a seal ring structure around a device layer of an IC die in a semiconductor die package. For example, voids may occur in a passivation layer around a metal pad structure at the top of the seal ring structure due to the shape of the metal pad structure. These voids may lead to other defects occurring in the IC die, such as delamination and film peeling in the passivation layer. In some cases, the delamination and film peeling in the passivation layer may become so severe that the delamination and film peeling propagates into a bonding layer above the passivation layer, which can cause debonding between the IC die and another IC die in the semiconductor die package. Thus, the voids that occur in the passivation layer around the metal pad structure at the top of the seal ring structure may lead to reduced reliability and/or failure of the semiconductor die package.

In some implementations described herein, a recess is formed through a passivation layer of an IC die and into an opening in a metal pad structure at the top of a seal ring structure of the IC die. The recess is formed to open up any void that may have occurred in the passivation layer within the opening in the metal pad structure. This enables the recess (and thus, the void) to be filled in, which reduces the likelihood that the void might otherwise cause delamination and film peeling in the passivation layer. The recess (and thus, the void) may be filled in to form a bonding via and a bonding pad, which may be dummy structures or may be used to bond the IC die with another IC in the semiconductor die package. In this way, opening up the void and filling in the void may increase the reliability of the semiconductor die package, and may decrease the likelihood of die-to-die debonding and failure in the semiconductor die package, among other examples. Moreover, the process for filling in the void can be integrated into the overall bonding via/pad process for the IC die, thereby minimizing the complexity, cost, and time impact of filling in the voids.

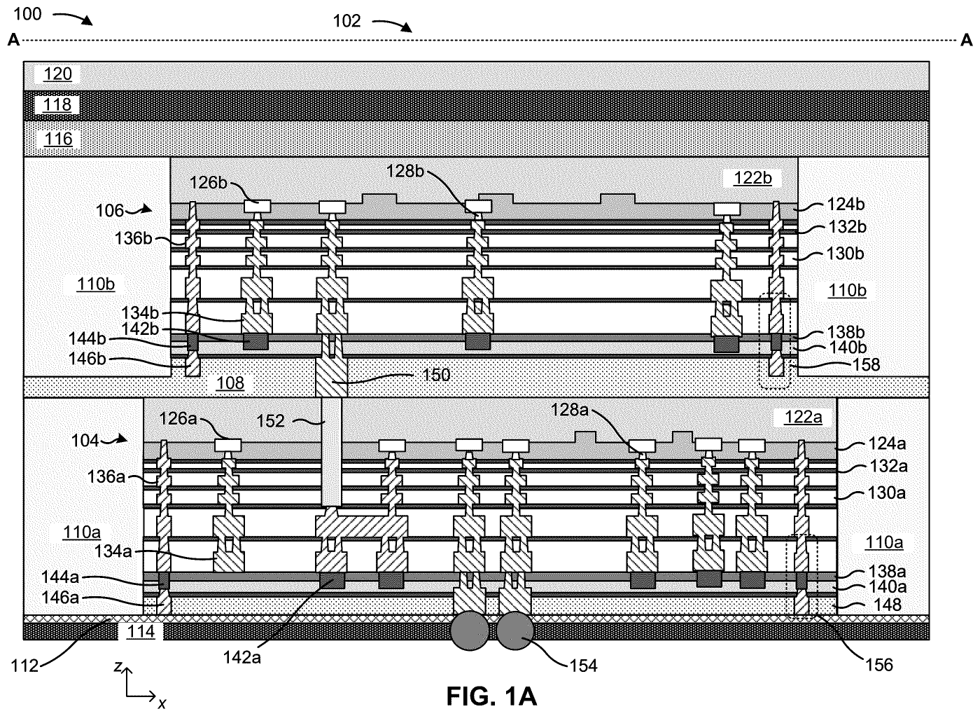

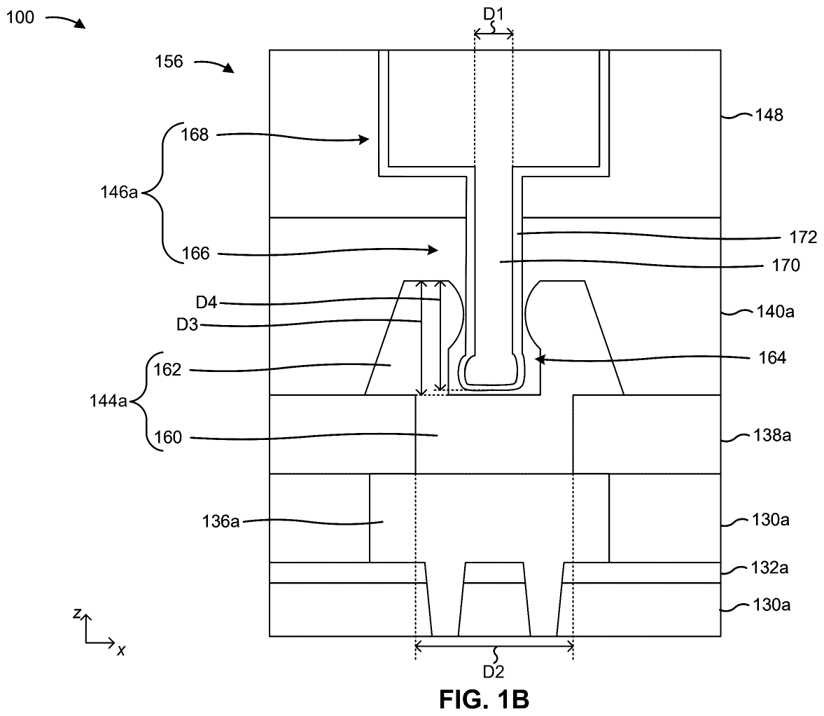

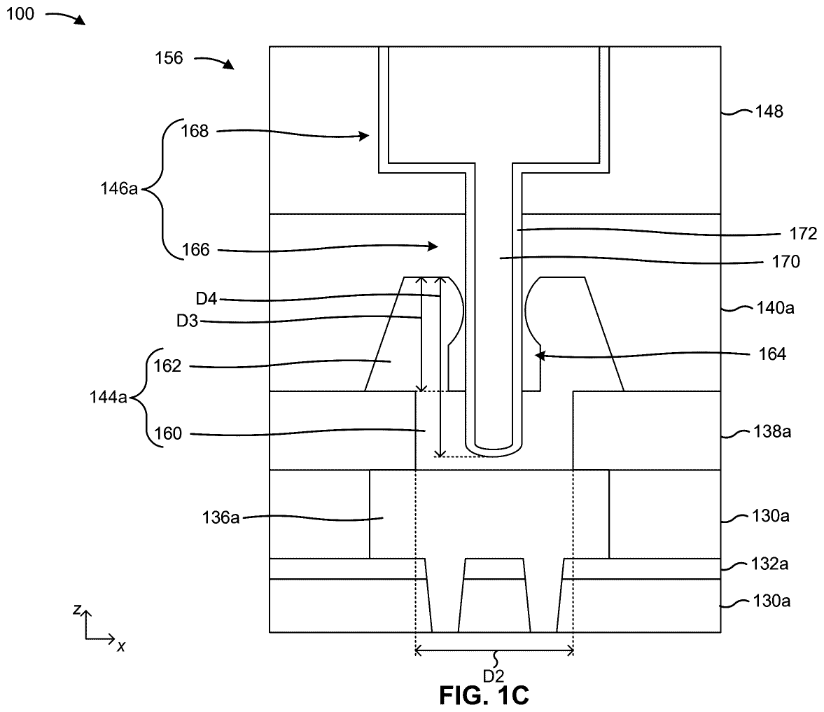

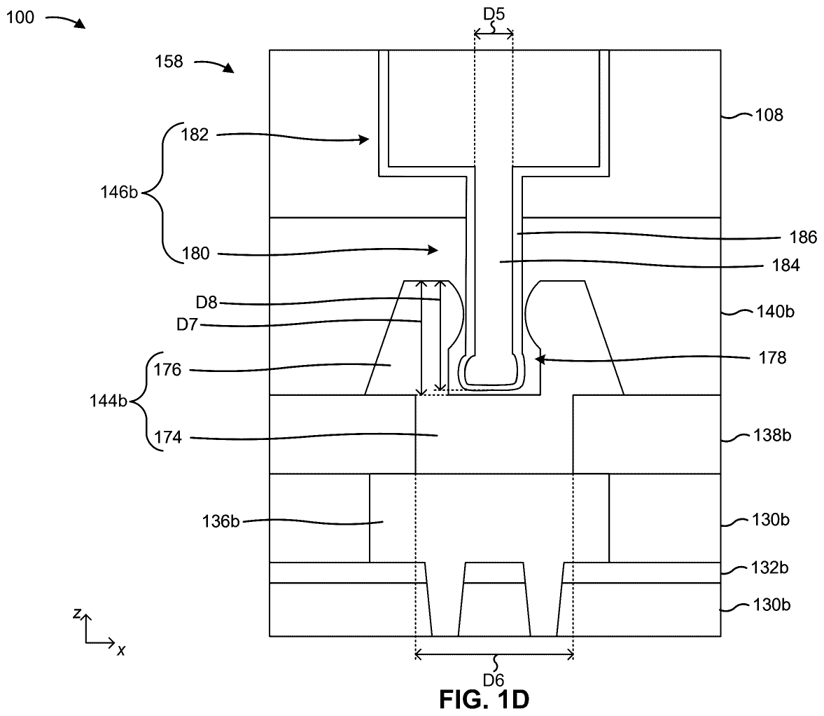

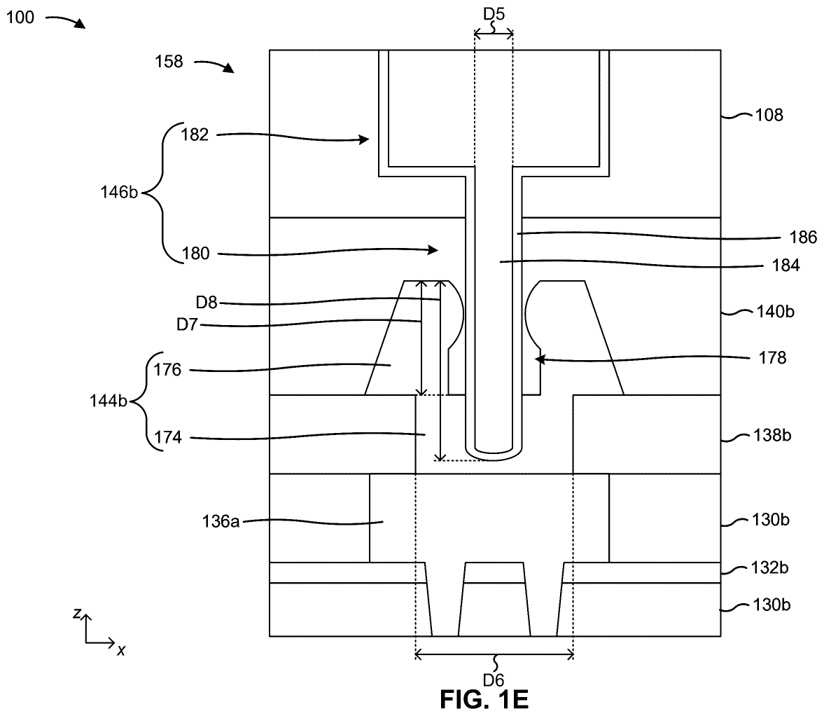

FIGS. 1A-1E are diagrams of an example 100 of a semiconductor die package 102 described herein. The semiconductor die package 102 includes a packaged semiconductor device that includes a plurality of active IC dies or chips. The plurality of active IC dies may be vertically arranged and/or stacked in the semiconductor die package 102 using three-dimensional (3D) packaging techniques such as direct bonding.

FIG. 1A illustrates a cross-section view of the semiconductor die package 102. As shown in FIG. 1A, the semiconductor die package 102 includes an IC die 104. The IC die 104 is an IC die that includes active integrated circuits of the semiconductor die package 102 and is configured perform various processing functions of the semiconductor die package 102. Examples for the IC die 104 includes a logic IC die, a memory IC die, a high-bandwidth memory (HBM) IC die, an input/output (I/O) die, a system-on-chip (SoC) IC die, a dynamic random access memory (DRAM) IC die, a complementary metal-oxide-semiconductor (CMOS) image sensor IC die, a silicon photonics IC die, a central processing unit (CPU) IC die, a graphics processing unit (GPU) IC die, a digital signal processing (DSP) IC die, an application specific integrated circuit (ASIC) IC die, and/or another type of active IC die.

In some implementations, the IC die 104 has an approximately square or rectangular top view shape. However, in other implementations, the IC die 104 may be approximately circle shaped (or generally round shaped), hexagon shaped, or another shape. Alternatively, the IC die 104 may include a non-standard shape or an amorphous shape.

As further shown in FIG. 1A, the semiconductor die package 102 further includes an IC die 106. The IC die 106 is included on the IC die 104 such that the IC dies 104 and 106 are stacked and vertically arranged in a z-direction in the semiconductor die package 102. In some implementations, the IC die 104 and the IC die 106 are the same type of active IC die. For example, the IC die 104 and the IC die 106 may each be a separate CPU die. In some implementations, the IC die 104 and the IC die 106 are different types of active IC dies. For example, the IC die 104 may be a CPU die, and the IC die 106 may be an I/O die or an HBM die.

As further shown in FIG. 1A, the IC dies 104 and 106 are bonded together at a bonding layer (or bonding film) 108. The bonding layer 108 includes one or more types of materials such as a silicon oxide (SiOₓ) (e.g., silicon dioxide (SiO₂)) and/or another type of dielectric bonding material. The IC dies 104 and 106 may be directly bonded (e.g., without an intervening interposer or another intervening structure) such that the IC dies 104 are 106 are stacked and vertically arranged in the z-direction in the semiconductor die package 102.

The areas around the sides of the IC die 104 are filled with a dielectric fill layer 110a such that the dielectric fill layer 110a surrounds the IC die 104, and the areas around the sides of the IC die 106 are filled with a dielectric fill layer 110b such that the dielectric fill layer 110b surrounds the IC die 106. The dielectric fill layers 110a and 110b may each include one or more dielectric materials such as a silicon oxide (SiOₓ) (e.g., silicon dioxide (SiO₂)), silicon oxynitride (SiON), and/or another type of dielectric material. The dielectric fill layers 110a and 110b may provide increased stability and electrical isolation for the IC dies 104 and 106.

The semiconductor die package 102 includes a plurality of passivation layers, including passivation layers 112 and 114 on a bottom side of the semiconductor die package 102, and passivation layers 116, 118, and 120 on a top side of the semiconductor die package 102, among other examples. In some implementations, the passivation layers 112, 114, 116, 118, and 120 may each include various types of electrically insulating materials, such as a silicon nitride (SiₓN_{y}), an undoped silicate glass (USG), a silicon oxide (SiOₓ) (e.g., silicon dioxide (SiO₂)), and/or another type of passivation material.

The IC dies 104 and 106 may each include a substrate (e.g., substrate 122a in the IC die 104 and substrate 122b in the IC die 106). The substrates 122a and 122b may each include a silicon (Si) substrate, a substrate formed of a material including silicon, a III-V compound semiconductor material substrate such as gallium arsenide (GaAs), a silicon on insulator (SOI) substrate, or another type of semiconductor substrate.

The IC dies 104 and 106 may each include a plurality of stacked layers, including an interlayer dielectric (ILD) layer (e.g., an ILD layer 124a on the substrate 122a and an ILD layer 124b on the substrate 122b). The ILD layers 124a and 124b may each include a silicon nitride (SiₓN_{y}), an oxide (e.g., a silicon oxide (SiOₓ) and/or another oxide material), and/or another type of dielectric material.

The IC dies 104 and 106 may each include IC devices (e.g., IC devices 126a in the substrate 122a and/or in the ILD layer 124a, IC devices 126b in the substrate 122b and/or in the ILD layer 124b). The IC devices 126a and 126b may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receives, optical circuits, and/or other types of front end semiconductor devices.

The IC dies 104 and 106 may each include contacts (e.g., contacts 128a, contacts 128b) that are electrically coupled with the IC devices. The contacts 128a may extend through the ILD layer 124a and may be electrically coupled with the IC devices 126a, and the contacts 128b may extend through the ILD layer 124b and may be electrically coupled with the IC devices 126b. The contacts 128a and 128b may include vias, plugs, and/or another type of elongated electrically conductive structures. The contacts 128a and 128b may include tungsten (W), cobalt (Co), ruthenium (Ru), titanium (Ti), aluminum (Al), and/or gold (Au), among other electrically conductive materials.

The IC dies 104 and 106 may each include a plurality of dielectric layers that are arranged in an alternating manner in the z-direction in the semiconductor die package 102. For example, the IC die 104 may include a plurality of alternating ILD layers 130a and etch stop layers (ESLs) 132a. The IC die 104 may include a plurality of conductive structures 134a in the ILD layers 130a and ESLs 132a. The substrate 122a, the ILD layer 124a, the IC devices 126a, and the contacts 128a may correspond to a device layer or front end of line (FEOL) region of the IC die 104, and the ILD layers 130a, the ESLs 132a, and the conductive structures 134a may correspond to an interconnect layer or back end of line (BEOL) region of the IC die 104.

Similarly, the IC die 106 may include a plurality of alternating ILD layers 130b and ESLs 132b. The IC die 106 may include a plurality of conductive structures 134b in the ILD layers 130b and ESLs 132b. The substrate 122b, the ILD layer 124b, the IC devices 126b, and the contacts 128b may correspond to a device layer or FEOL region of the IC die 106, and the ILD layers 130b, the ESLs 132b, and the conductive structures 134b may correspond to an interconnect layer or BEOL region of the IC die 106.

The ILD layers 130a and 130b may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 130a or 130b includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples. The ESLs 132a and 132b may each include a silicon nitride (SiₓN_{y}), silicon carbide (SiC), silicon oxynitride (SiON), and/or another suitable dielectric material.

The conductive structures 134a and 134b provide electrical routing that enables signals and/or power to be provided to and/or from the IC devices 126a and/or 126b. The conductive structures 134a and 134b may include a combination of trenches, metallization layers, conductive traces, vias, interconnects, and/or other types of conductive structures. The conductive structures 134a and 134b may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The IC die 104 may further include a seal ring structure 136a around the conductive structures 134a and surrounding the IC devices 126a to provide structural rigidity to the IC die 104 and to protect the conductive structures 134a and IC devices 126a from humidity ingress and other contaminants. The IC die 106 may similarly include a seal ring structure 136b around the conductive structures 134b and surrounding the IC devices 126b to provide structural rigidity to the IC die 106 and to protect the conductive structures 134b and IC devices 126b from humidity ingress and other contaminants. The seal ring structures 136a and 136b may each include a vertical arrangement of conductive structures, such as trenches, vias, metallization layers, interconnects, and/or other types of conductive structures. The interconnected conductive structures of the seal ring structures 136a and 136b may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The IC die 104 may include passivation layers 138a and 140a over and/or on the plurality of alternating dielectric layers (e.g., the ILD layers 130a and the ESLs 132a) to passivate the interconnect layer of the IC die 104. Similarly, the IC die 106 may include passivation layers 138b and 140b over and/or on the plurality of alternating dielectric layers (e.g., the ILD layers 130b and the ESLs 132b) to passivate the interconnect layer of the IC die 106.

Metal pad structures 142a may be included over and/or on the conductive structures 134a, and metal pad structures 144a may be included over and/or on the seal ring structure 136a. The metal pad structures 142a may be coupled to the conductive structures 134a, and metal pad structures 144a may be coupled to the seal ring structure 136a.

Metal pad structures 142b may be included over and/or on the conductive structures 134b, and metal pad structures 144b may be included over and/or on the seal ring structure 136b. The metal pad structures 142b may be coupled to the conductive structures 134b, and metal pad structures 144b may be coupled to the seal ring structure 136b.

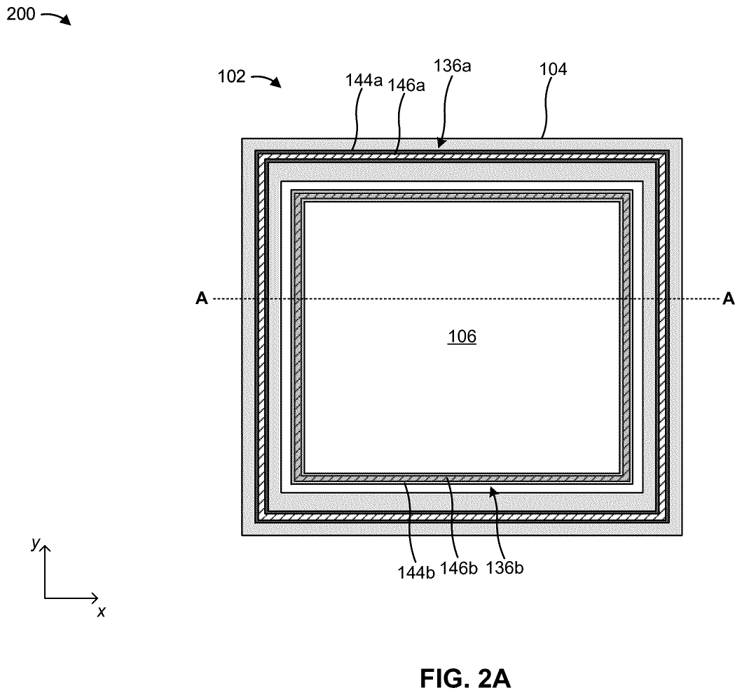

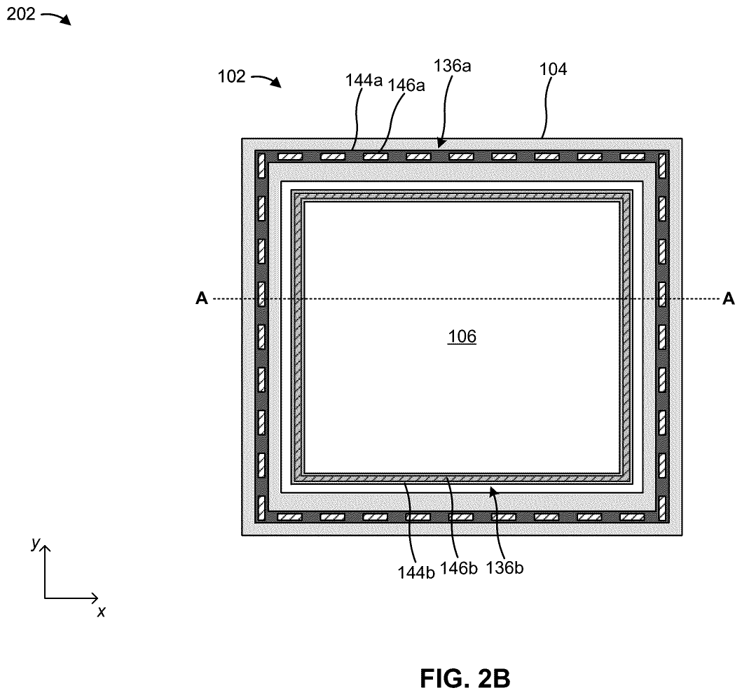

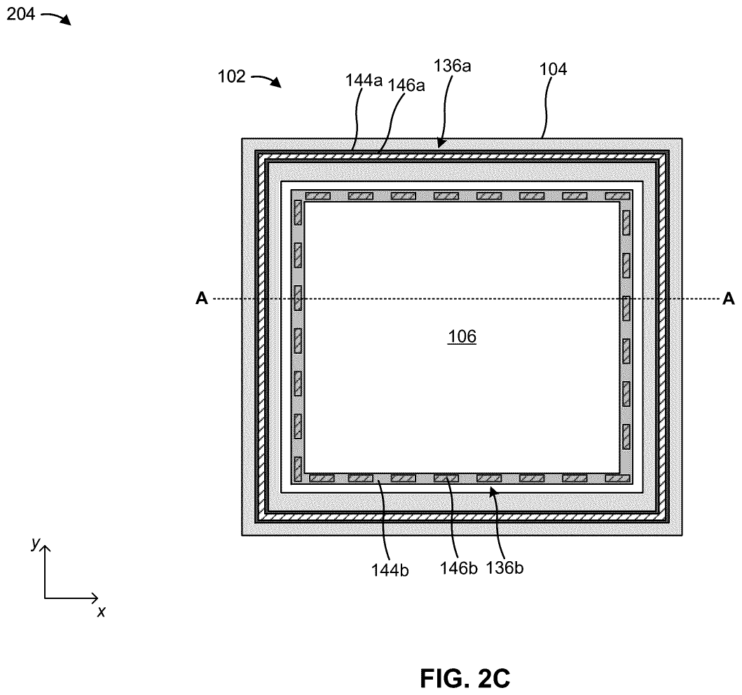

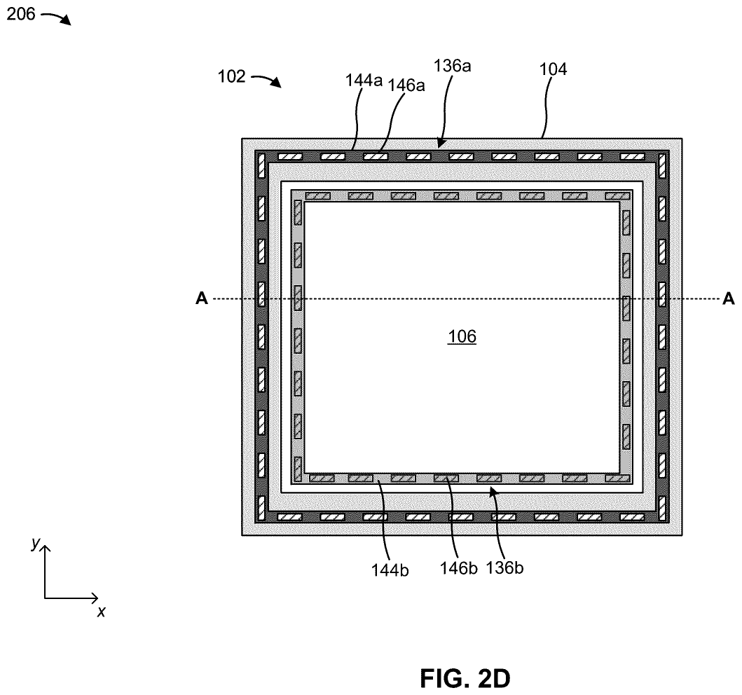

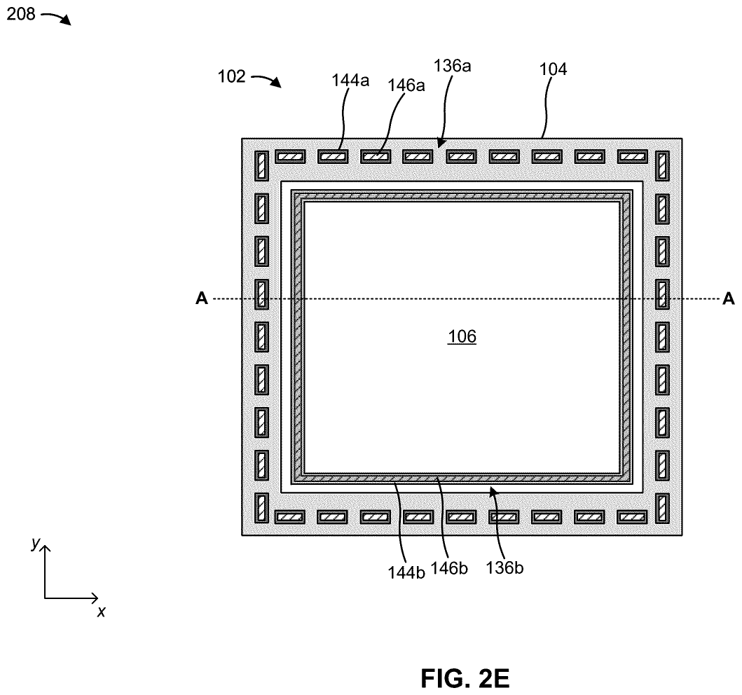

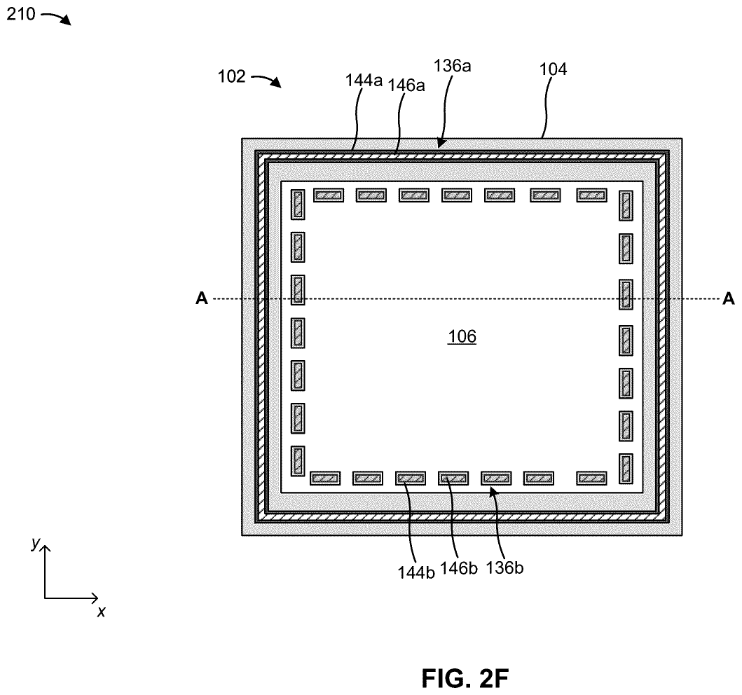

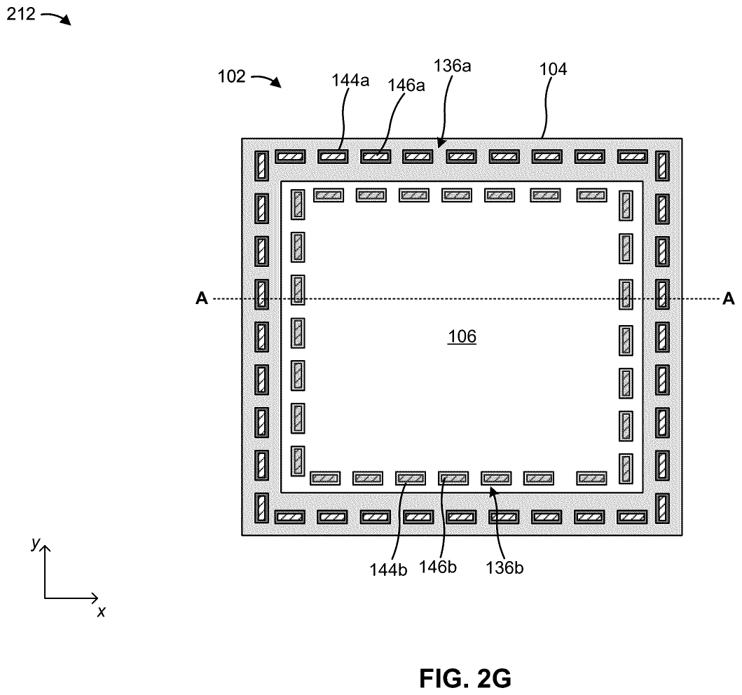

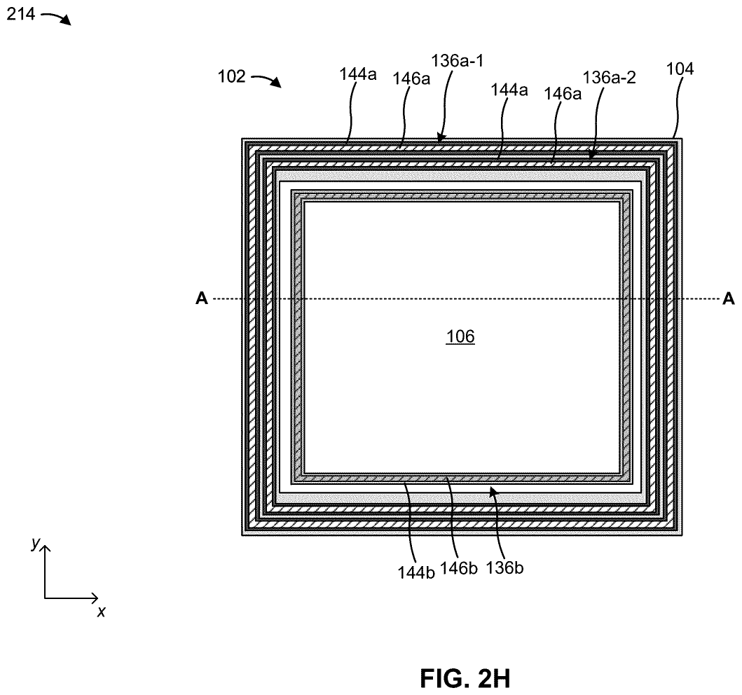

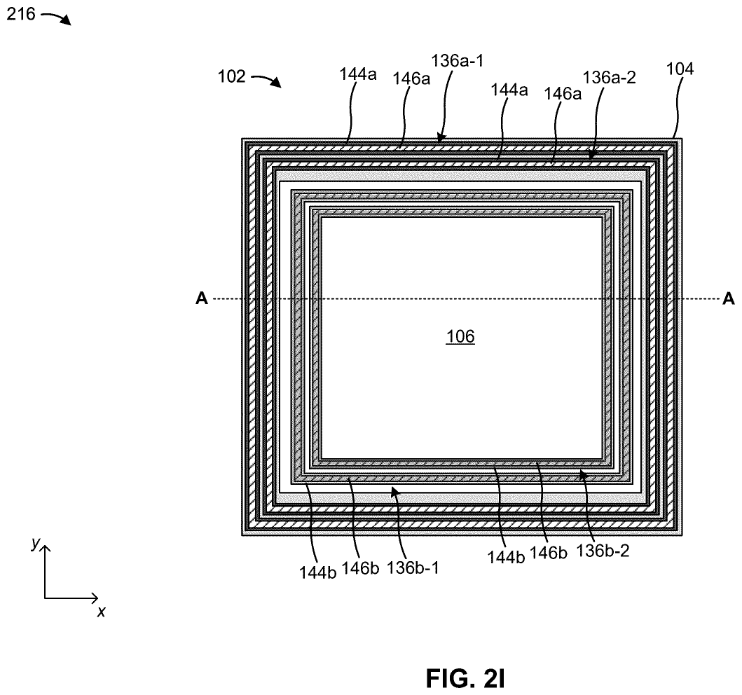

The metal pad structures 142a, 144a, 142b, and 144b may each include aluminum (Al), aluminum copper (AlCu), and/or another metal material. The seal ring structures 136a and 136b may further include bonding structures 146a and 146b, respectively. The bonding structures 146a may be coupled to the metal pad structures 144a, and the bonding structures 146b may be coupled to the metal pad structures 144b. The bonding structures 146a and 146b may each include tungsten (W), cobalt (Co), ruthenium (Ru), titanium (Ti), aluminum (Al), copper (Cu), gold (Au), and/or a combination thereof, among other examples of electrically conductive materials. Additional details of the bonding structures 146a and 146b are described in connection with FIGS. 1B-1E and 2A-2I, among other examples.

The IC die 104 further includes a bonding layer 148, which is used to bond the IC die 104 to a carrier substrate during manufacturing of the semiconductor die package 102. The bonding layer 148 includes one or more types of materials such as a silicon oxide (SiOₓ) (e.g., silicon dioxide (SiO₂)) and/or another type of dielectric bonding material.

The IC die 106 may further include bonding pads 150 that enable the IC die 106 to be bonded to a die-to-die interconnect 152 of the IC die 104. The bonding pads 150 may each include tungsten (W), cobalt (Co), ruthenium (Ru), titanium (Ti), aluminum (Al), copper (Cu), gold (Au), and/or a combination thereof, among other examples of electrically conductive materials. The die-to-die interconnect 152 may include a die-to-die wire, a through substrate via (TSV), or another type of die-to-die interconnect. The die-to-die interconnect 152 also electrically connects the IC dies 104 and 106. In this way, electrical signals and/or power may be provided between the IC dies 104 and 106 through the die-to-die interconnect 152. The die-to-die interconnect 152 includes a conductive material such as tungsten (W), cobalt (Co), ruthenium (Ru), titanium (Ti), aluminum (Al), copper (Cu), gold (Au), and/or a combination thereof, among other examples of conductive materials.

The topmost layer of conductive structures 134a (e.g., a top metal layer) may be coupled to connection structures 154 at the top of the semiconductor die package 102 (which is facing downward in FIG. 1A). The connection structures 154 may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures that enable the semiconductor die package 102 to be connected to a substrate or a socket, among other examples.

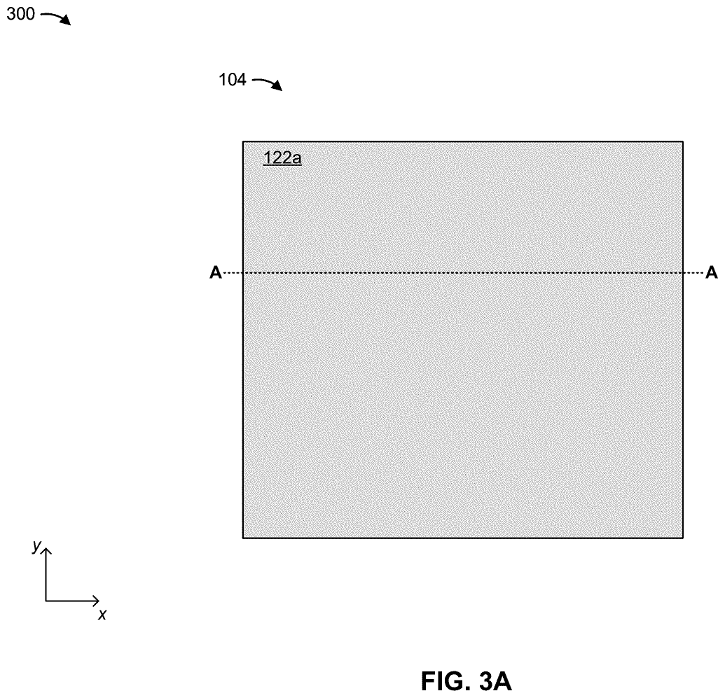

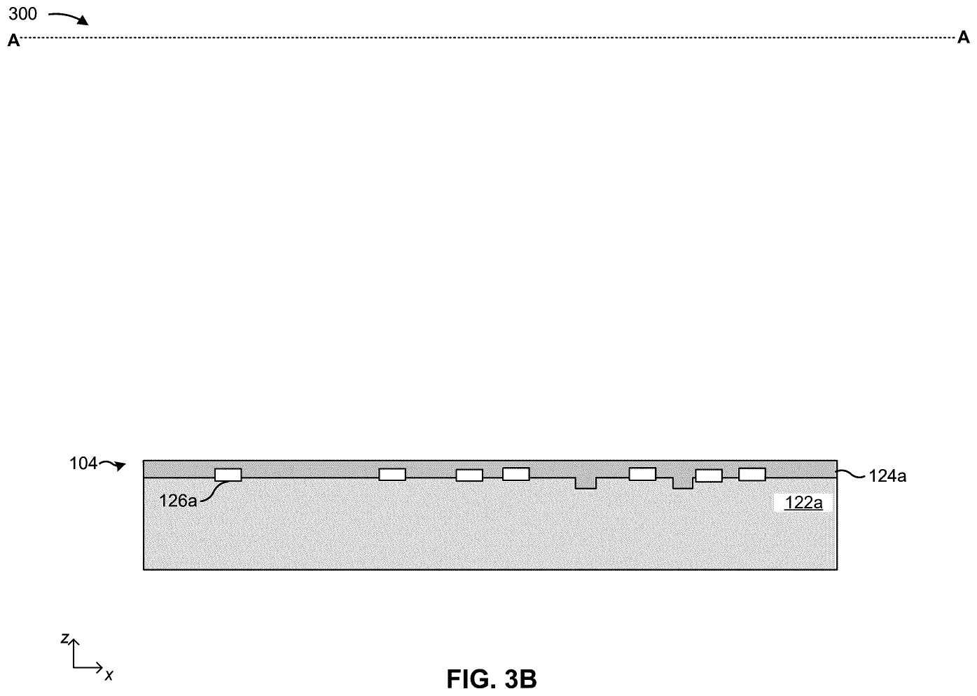

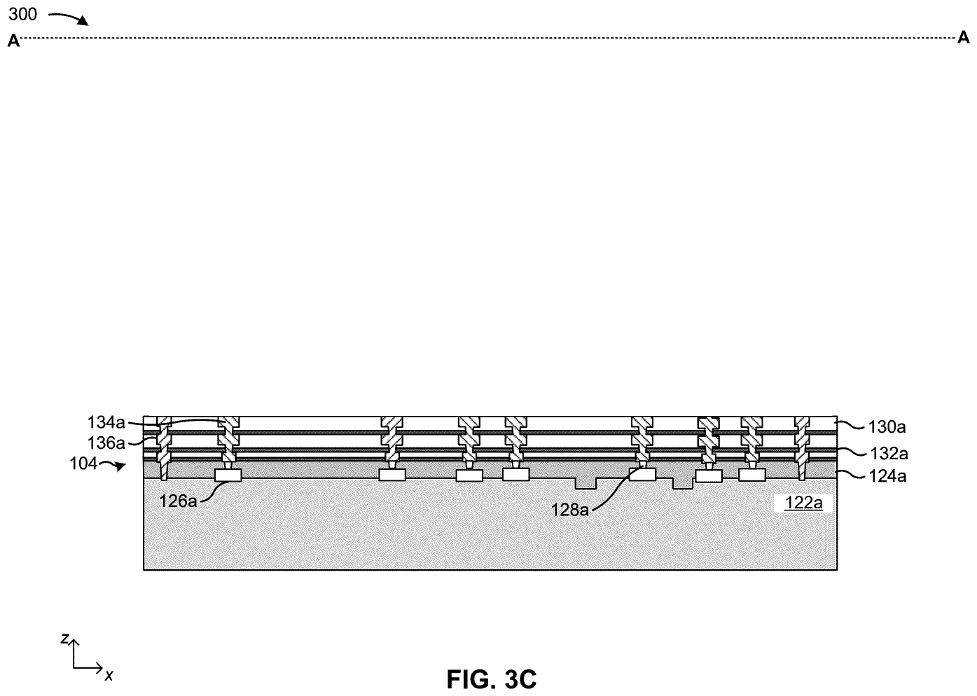

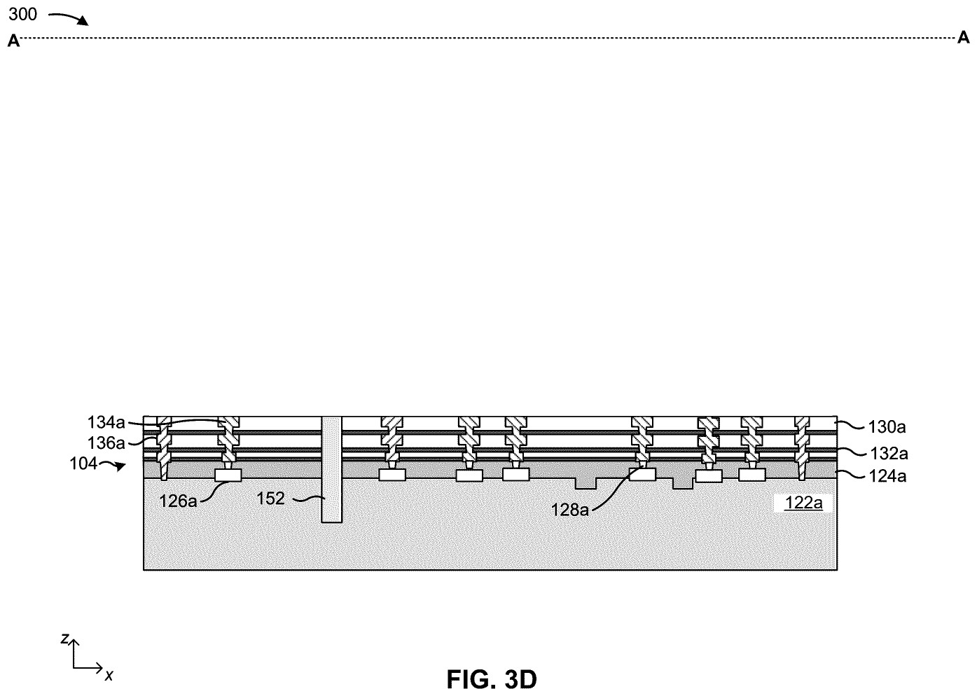

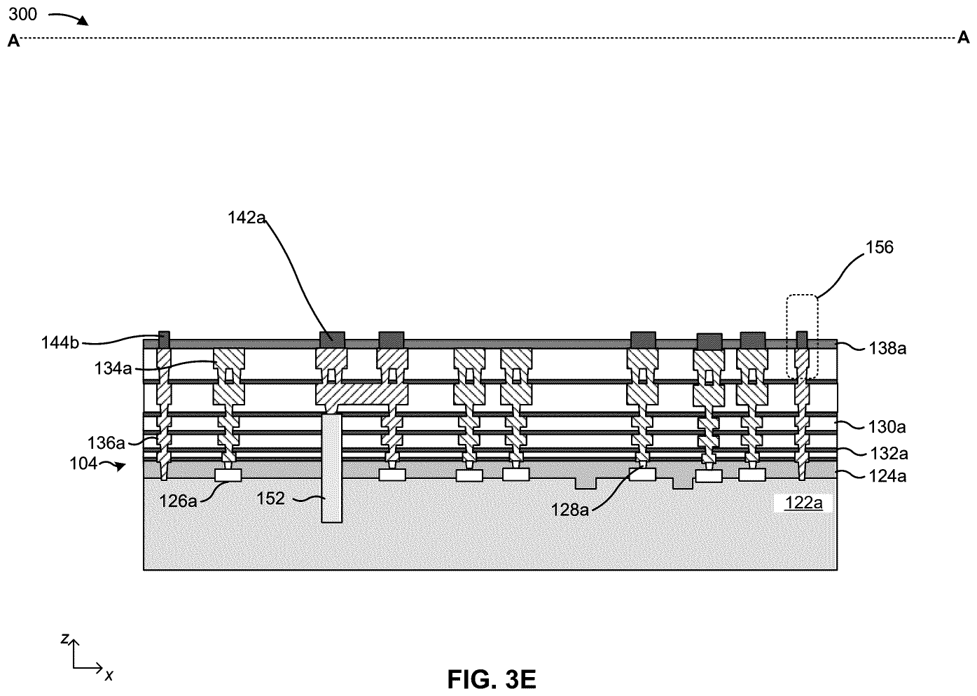

FIGS. 1B and 1C illustrate detailed views of a portion 156 of the IC die 104 indicated in FIG. 1A. FIGS. 1D and 1E illustrate detailed views of a portion 158 of the IC die 106 indicated in FIG. 1A. Additional figures herein, including one or more of FIGS. 2A-2I, 3A-3E, and/or 6A-6H, among other examples, refer back to FIG. 1A to indicate the location of the cross-section view along the line A-A in the semiconductor die package 102 and/or other semiconductor die packages described herein.

As shown in FIG. 1B, a topmost conductive structure (e.g., a top metal layer) of the seal ring structure 136a of the IC die 104 is coupled to a metal pad structure 144a on the seal ring structure 136a. The metal pad structure 144a may include a bottom portion 160 that is in contact (e.g., in physical contact) with a top surface of the topmost conductive structure of the seal ring structure 136a. The metal pad structure 144a may further include a top portion 162 above the bottom portion 160. The bottom portion 160 may be included in, and may extend through, the passivation layer 138a, and the top portion 162 may be included in the passivation layer 140a above the passivation layer 138a.

As further shown in FIG. 1B, an opening 164 is included in the top portion 162 of the metal pad structure 144a. The opening 164 may occur during formation of the metal pad structure 144a (e.g., as a result of the techniques and/or processes used to form the metal pad structure 144a). For example, the metal pad structure 144a may be deposited in a recess in the passivation layer 138a above the topmost conductive structure of the seal ring structure 136a, and the material of the metal pad structure 144a may be deposited such that the metal pad structure 144a extends above the passivation layer 138a so as to ensure that the recess is fully filled with the material of the metal pad structure 144a. The top portion 162 that extends above the recess may not fully coalesce, resulting in the opening 164 extending into the top portion 162.

The width of the opening 164 extending into the top portion 162 may be narrow, resulting in poor gap-filling performance in the opening 164 when forming the passivation layer 140a. The narrow width of the opening 164 restricts the flow of material of the passivation layer 140a, resulting in an increased likelihood of voids forming in the passivation layer 140a within the opening 164 of the metal pad structure 144a.

To reduce, minimize, and/or prevent the likelihood of a void within the opening 164 causing delamination in the passivation layer 140a (which might otherwise propagate into the bonding layer 148 above the passivation layer 140a), the area within the opening 164 is filled in with a via portion 166 of the bonding structure 146a on the seal ring structure 136a. The via portion 166 of the bonding structure 146a extends through the passivation layer 140a and into the opening 164 of the metal pad structure 144a. The bonding structure 146a may also include a trench portion 168 above the via portion 166. The trench portion 168 may be included in the bonding layer 148. The via portion 166 of the bonding structure 146a may correspond to a bonding via of the bonding structure 146a, and the trench portion 168 of the bonding structure 146a may correspond to a bonding pad of the bonding structure 146a.

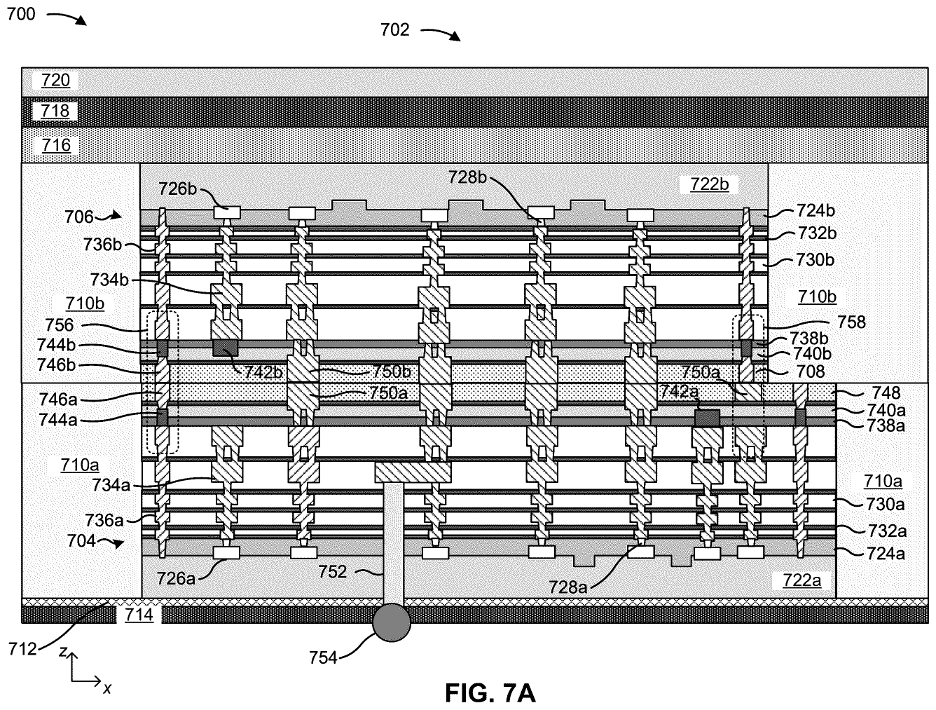

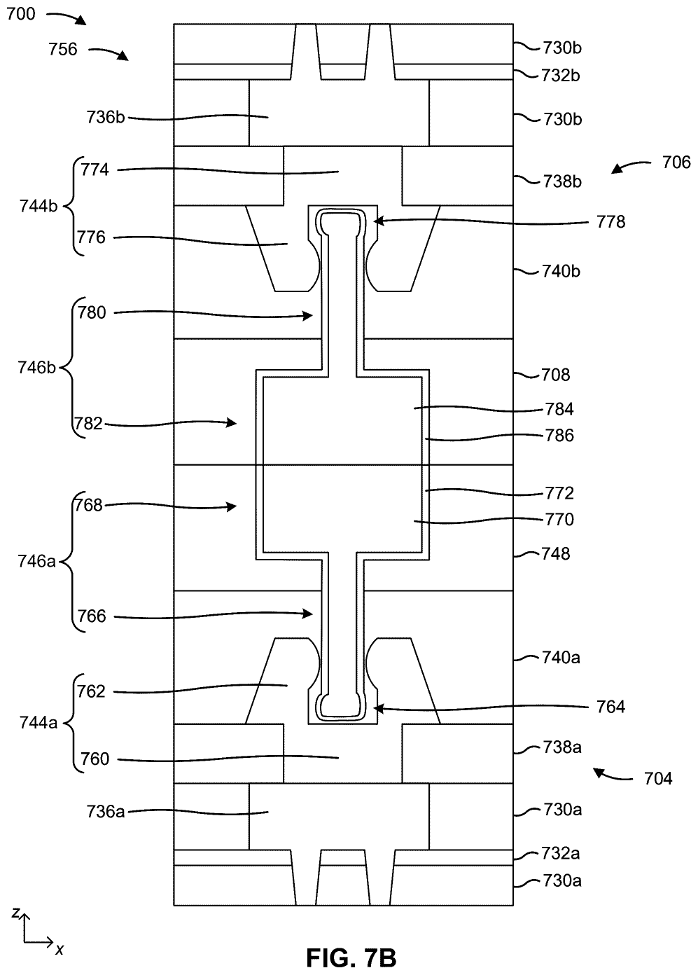

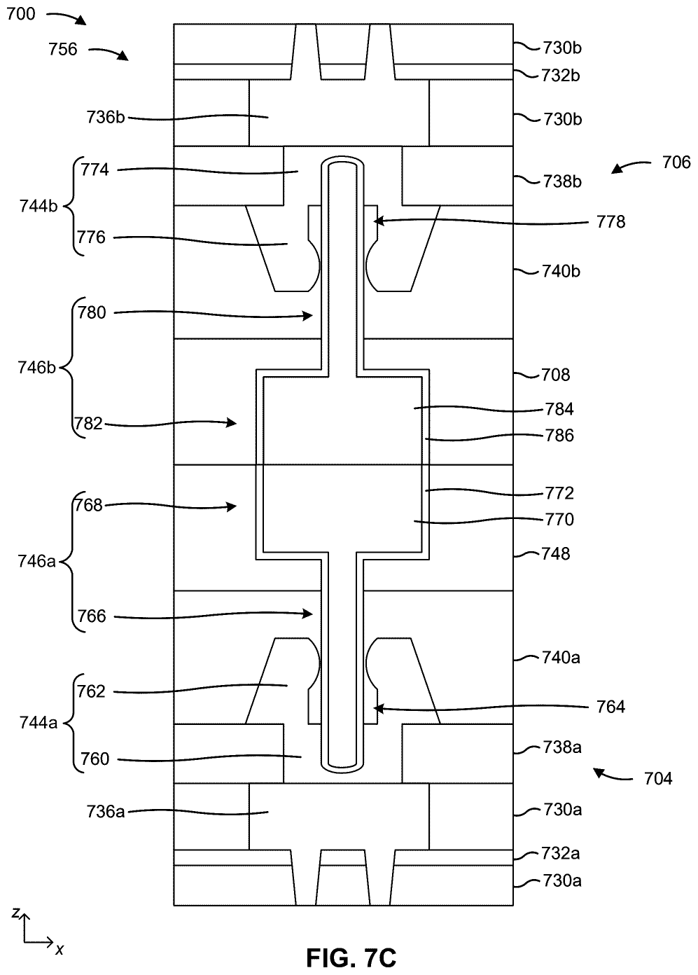

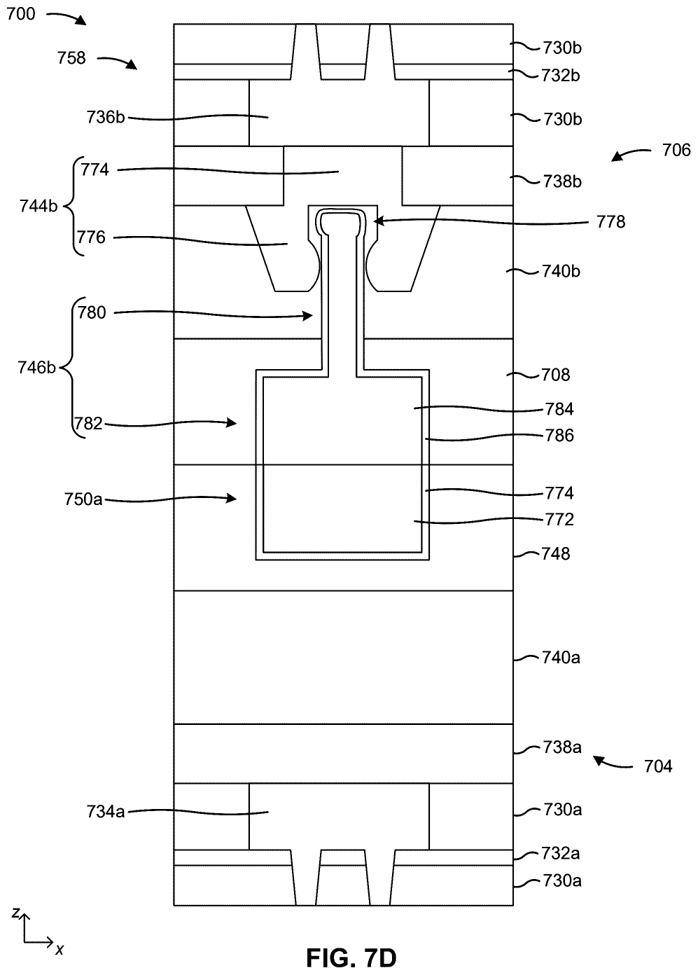

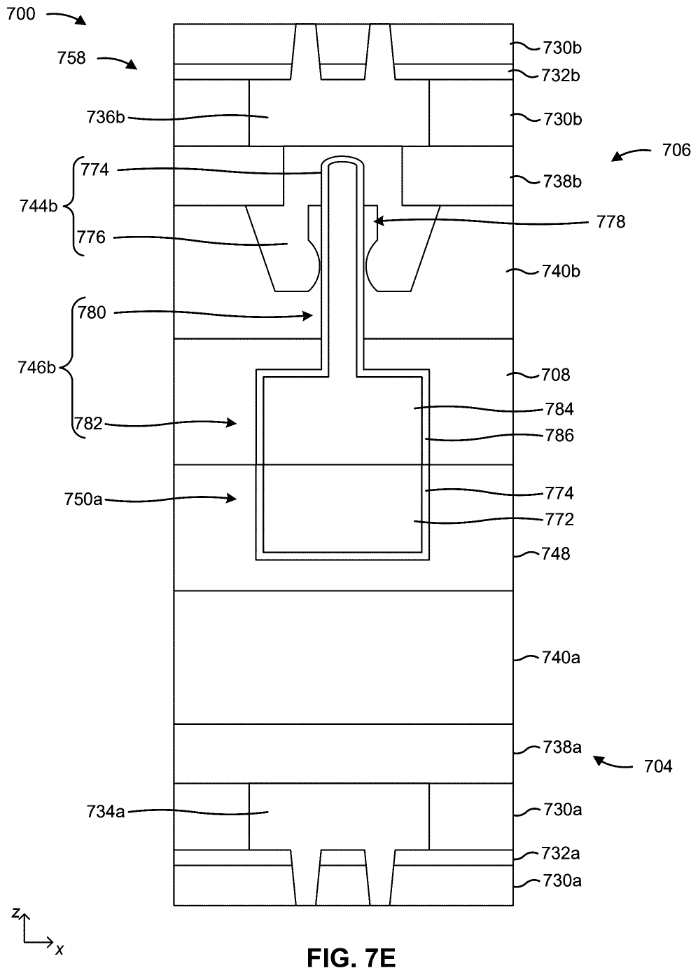

In some implementations, the via portion 166 and the trench portion 168 of the bonding structure 146a are used for bonding purposes to bond the IC die 104 and the IC die 106, as illustrated in FIGS. 7A-7E, in addition to removing voids from the passivation layer 140a. In these implementations, the trench portion 168 is bonded to a trench portion 182 of a bonding structure 146b on the seal ring structure 136b of the IC die 106. In some implementations, the via portion 166 and the trench portion 168 of the bonding structure 146a are not used for bonding purposes and instead are dummy structures that are only included to remove voids from the passivation layer 140a. In these implementations, the trench portion 168 is not bonded to a trench portion 182 of a bonding structure 146b on the seal ring structure 136b of the IC die 106.

As further shown in FIG. 1B, the bonding structure 146a includes a metal layer 170 and a liner 172 between the metal layer 170 and the surrounding dielectric layers of the IC die 104. The metal layer 170 in the via portion 166 may correspond to a conductive via structure, and the metal layer 170 in the trench portion 168 may correspond to a conductive trench structure. The metal layer 170 may include tungsten (W), cobalt (Co), ruthenium (Ru), titanium (Ti), aluminum (Al), and/or gold (Au), among other electrically conductive materials.

The liner 172 may include a tantalum nitride (TaN) barrier layer, a titanium (Ti) or titanium nitride (TiN) barrier layer, a silicon oxide (SiOₓ such as SiO₂) liner and/or another suitable liner that extends along the sidewalls of the via portion 166 and along the sidewalls of the trench portion 168. In some implementations, the liner 172 is included between the bottom surface of the trench portion 168 and the bonding layer 148, and the liner 172 is omitted between the via portion 166 and the trench portion 168 to enable a low contact resistance to be achieved between the via portion 166 and the trench portion 168. Alternatively, the liner 172 may be included between the via portion 166 and the trench portion 168.

As further shown in FIG. 1B, the bonding structure 146a and the metal pad structure 144a may have one or more dimensions, including a dimension D1, a dimension D2, a dimension D3, and/or a dimension D4, among other examples. The dimension D1 corresponds to a lateral width of the via portion 166 of the bonding structure 146a. The dimension D2 corresponds to a lateral width of the bottom portion 160 of the metal pad structure 144a. The dimension D3 corresponds to a z-direction thickness of the top portion 162 of the metal pad structure 144a. The dimension D4 corresponds to a depth to which the via portion 166 of the bonding structure 146a extends into the opening 164.

The lateral width of the via portion 166 of the bonding structure 146a may be less than the lateral width of the bottom portion 160 of the metal pad structure 144a (e.g., dimension D1<dimension D2) but greater than approximately 1/100^{th} of the lateral width of the bottom portion 160 of the metal pad structure 144a (e.g., dimension D1> 1/100^{th} dimension D2). If the lateral width of the via portion 166 of the bonding structure 146a is less than approximately 1/100^{th} the lateral width of the bottom portion 160 of the metal pad structure 144a, the via portion 166 of the bonding structure 146a may be too narrow to achieve sufficient gap-filling performance for the via portion 166, resulting in voids being formed in the via portion 166. Moreover, if the lateral width of the via portion 166 of the bonding structure 146a is less than approximately 1/100^{th} of the lateral width of the bottom portion 160 of the metal pad structure 144a, the via portion 166 of the bonding structure 146a may be too narrow to fully fill in voids in the passivation layer 140a within the opening 164 in the top portion 162 of the metal pad structure 144a. If the lateral width of the via portion 166 of the bonding structure 146a is greater than the lateral width of the bottom portion 160 of the metal pad structure 144a, material from the bonding structure 146a may diffuse through the metal pad structure 144a and into the passivation layer 138a. If the lateral width of the via portion 166 of the bonding structure 146a is greater than approximately 1/100^{th} of the lateral width of the bottom portion 160 of the metal pad structure 144a and less than the lateral width of the bottom portion 160 of the metal pad structure 144a, the via portion 166 may fully fill in voids in the passivation layer 140a within the opening 164 in the top portion 162 of the metal pad structure 144a, while achieving void-free formation of the via portion 166 and minimizing material diffusion from the via portion 166. However, other values and ranges for the lateral width of the via portion 166 of the bonding structure 146a are within the scope of the present disclosure.

The depth to which the via portion 166 of the bonding structure 146a extends into the opening 164 may be less than the combined z-direction thickness of the bottom portion 160 and the top portion 162 of the metal pad structure 144a (e.g., dimension D4<dimension D3 plus the thickness of the passivation layer 138a) but greater than approximately 1/100^{th} of the z-direction thickness of the top portion 162 of the metal pad structure 144a (e.g., dimension D4> 1/100^{th} dimension D3). If the depth to which the via portion 166 of the bonding structure 146a extends into the opening 164 is less than approximately 1/100^{th} of the z-direction thickness of the top portion 162 of the metal pad structure 144a, the via portion 166 may extend to an insufficient depth in the opening 164 to fully fill in voids in the passivation layer 140a within the opening 164 in the top portion 162 of the metal pad structure 144a. If the depth to which the via portion 166 of the bonding structure 146a extends into the opening 164 is greater than the combined z-direction thickness of the bottom portion 160 and the top portion 162 of the metal pad structure 144a, the via portion 166 of the bonding structure 146a may puncture through the metal pad structure 144a, causing a disconnect between the metal pad structure 144a and the underlying seal ring structure 136a. If the depth to which the via portion 166 of the bonding structure 146a extends into the opening 164 is less than the combined z-direction thickness of the bottom portion 160 and the top portion 162 of the metal pad structure 144a but greater than approximately 1/100^{th} of the z-direction thickness of the top portion 162 of the metal pad structure 144a, the via portion 166 may fully fill in voids in the passivation layer 140a within the opening 164 in the top portion 162 of the metal pad structure 144a without causing a disconnect between the metal pad structure 144a and the underlying seal ring structure 136a. However, other values and ranges for the depth to which the via portion 166 of the bonding structure 146a extends into the opening 164 are within the scope of the present disclosure.

FIG. 1C illustrates an alternative implementation of the via portion 166 of the bonding structure 146a in which the via portion 166 of the bonding structure 146a extends through the opening 164 in the top portion 162 of the metal pad structure 144a and into a portion of the bottom portion 160 of the metal pad structure 144a. In other words, the depth to which the via portion 166 of the bonding structure 146a extends into the opening 164 is greater than the z-direction thickness of the top portion 162 of the metal pad structure 144a (e.g., dimension D4>dimension D3), but is still less than the combined z-direction thickness of the bottom portion 160 and the top portion 162 of the metal pad structure 144a (e.g., dimension D4<dimension D3 plus the thickness of the passivation layer 138a). In some implementations, the via portion 166 of the bonding structure 146a may be formed to extend through the opening 164 in the top portion 162 of the metal pad structure 144a and into a portion of the bottom portion 160 of the metal pad structure 144a to ensure that any voids in the passivation layer 140a within the opening 164 are fully opened and filled in with the via portion 166.

As shown in the detailed view of the portion 158 of the IC die 106 in FIG. 1D, a topmost conductive structure (e.g., a top metal layer) of the seal ring structure 136b of the IC die 106 is coupled to a metal pad structure 144b on the seal ring structure 136b. The metal pad structure 144b may include a bottom portion 174 that is in contact (e.g., in physical contact) with a top surface of the topmost conductive structure of the seal ring structure 136b. The metal pad structure 144b may further include a top portion 176 above the bottom portion 174. The bottom portion 174 may be included in, and may extend through, the passivation layer 138b, and the top portion 176 may be included in the passivation layer 140b above the passivation layer 138b.

As further shown in FIG. 1D, an opening 178 is included in the top portion 176 of the metal pad structure 144b. To reduce, minimize, and/or prevent the likelihood of a void within the opening 178 causing delamination in the passivation layer 140b (which might otherwise propagate into the bonding layer 108 above the passivation layer 140b), the area within the opening 178 is filled in with a via portion 180 of the bonding structure 146b on the seal ring structure 136b. The via portion 180 of the bonding structure 146b extends through the passivation layer 140b and into the opening 178 of the metal pad structure 144b. The bonding structure 146b may also include a trench portion 182 above the via portion 180. The trench portion 182 may be included in the bonding layer 108. The via portion 180 of the bonding structure 146b may correspond to a bonding via of the bonding structure 146b, and the trench portion 182 of the bonding structure 146b may correspond to a bonding pad of the bonding structure 146b.

In some implementations, the via portion 180 and the trench portion 182 of the bonding structure 146b are used for bonding purposes to bond the IC die 104 and the IC die 106, as illustrated in FIGS. 7A-7E, in addition to removing voids from the passivation layer 140b. In these implementations, the trench portion 182 is bonded to a trench portion 168 of a bonding structure 146a on the seal ring structure 136a of the IC die 104. In some implementations, the via portion 180 and the trench portion 182 of the bonding structure 146b are not used for bonding purposes and instead are dummy structures that are only included to remove voids from the passivation layer 140b. In these implementations, the trench portion 182 is not bonded to a trench portion 168 of a bonding structure 146a on the seal ring structure 136a of the IC die 104.

As further shown in FIG. 1D, the bonding structure 146b includes a metal layer 184 and a liner 186 between the metal layer 184 and the surrounding dielectric layers of the IC die 106. The metal layer 184 in the via portion 180 may correspond to a conductive via structure, and the metal layer 184 in the trench portion 182 may correspond to a conductive trench structure. The metal layer 184 may include tungsten (W), cobalt (Co), ruthenium (Ru), titanium (Ti), aluminum (Al), and/or gold (Au), among other electrically conductive materials.

The liner 186 may include a tantalum nitride (TaN) barrier layer, a titanium (Ti) or titanium nitride (TiN) barrier layer, a silicon oxide (SiOₓ such as SiO₂) liner, and/or another suitable liner that extends along the sidewalls of the via portion 180 and along the sidewalls of the trench portion 182. In some implementations, the liner 186 is included between the bottom surface of the trench portion 182 and the bonding layer 108, and the liner 186 is omitted between the via portion 180 and the trench portion 182 to enable a low contact resistance to be achieved between the via portion 180 and the trench portion 182. Alternatively, the liner 186 may be included between the via portion 180 and the trench portion 182.

As further shown in FIG. 1D, the bonding structure 146b and the metal pad structure 144b may have one or more dimensions, including a dimension D5, a dimension D6, a dimension D7, and/or a dimension D8, among other examples. The dimension D5 corresponds to a lateral width of the via portion 180 of the bonding structure 146b. The dimension D6 corresponds to a lateral width of the bottom portion 174 of the metal pad structure 144b. The dimension D7 corresponds to a z-direction thickness of the top portion 176 of the metal pad structure 144b. The dimension D8 corresponds to depth to which the via portion 180 of the bonding structure 146b extends into the opening 178.

The lateral width of the via portion 180 of the bonding structure 146b may be less than the lateral width of the bottom portion 174 of the metal pad structure 144b (e.g., dimension D5<dimension D6) but greater than approximately 1/100^{th} of the lateral width of the bottom portion 174 of the metal pad structure 144b (e.g., dimension D5> 1/100^{th} dimension D6). If the lateral width of the via portion 180 of the bonding structure 146b is less than approximately 1/100^{th} the lateral width of the bottom portion 174 of the metal pad structure 144b, the via portion 180 of the bonding structure 146b may be too narrow to achieve sufficient gap-filling performance for the via portion 180, resulting in voids being formed in the via portion 180. Moreover, if the lateral width of the via portion 180 of the bonding structure 146b is less than approximately 1/100^{th} of the lateral width of the bottom portion 174 of the metal pad structure 144b, the via portion 180 of the bonding structure 146b may be too narrow to fully fill in voids in the passivation layer 140b within the opening 178 in the top portion 176 of the metal pad structure 144b. If the lateral width of the via portion 180 of the bonding structure 146b is greater than the lateral width of the bottom portion 174 of the metal pad structure 144b, material from the bonding structure 146b may diffuse through the metal pad structure 144b and into the passivation layer 138b. If the lateral width of the via portion 180 of the bonding structure 146b is greater than approximately 1/100^{th} of the lateral width of the bottom portion 174 of the metal pad structure 144b and less than the lateral width of the bottom portion 174 of the metal pad structure 144b, the via portion 180 may fully fill in voids in the passivation layer 140a within the opening 178 in the top portion 176 of the metal pad structure 144b, while achieving void-free formation of the via portion 180 and minimizing material diffusion from the via portion 180. However, other values and ranges for the lateral width of the via portion 180 of the bonding structure 146b are within the scope of the present disclosure.

The depth to which the via portion 180 of the bonding structure 146b extends into the opening 178 may be less than the combined z-direction thickness of the bottom portion 174 and the top portion 176 of the metal pad structure 144b (e.g., dimension D8<dimension D7 plus the thickness of the passivation layer 138b) but greater than approximately 1/100^{th} of the z-direction thickness of the top portion 176 of the metal pad structure 144b (e.g., dimension D8> 1/100^{th} dimension D7). If the depth to which the via portion 180 of the bonding structure 146b extends into the opening 178 is less than approximately 1/100^{th} of the z-direction thickness of the top portion 176 of the metal pad structure 144b, the via portion 180 may extend to an insufficient depth in the opening 178 to fully fill in voids in the passivation layer 140b within the opening 178 in the top portion 176 of the metal pad structure 144b. If the depth to which the via portion 180 of the bonding structure 146b extends into the opening 178 is greater than the combined z-direction thickness of the bottom portion 174 and the top portion 176 of the metal pad structure 144b, the via portion 180 of the bonding structure 146b may puncture through the metal pad structure 144b, causing a disconnect between the metal pad structure 144b and the underlying seal ring structure 136b. If the depth to which the via portion 180 of the bonding structure 146b extends into the opening 178 is less than the combined z-direction thickness of the bottom portion 174 and the top portion 176 of the metal pad structure 144b but greater than approximately 1/100^{th} of the z-direction thickness of the top portion 176 of the metal pad structure 144b, the via portion 180 may fully fill in voids in the passivation layer 140b within the opening 178 in the top portion 176 of the metal pad structure 144b without causing a disconnect between the metal pad structure 144b and the underlying seal ring structure 136b. However, other values and ranges for the depth to which the via portion 180 of the bonding structure 146b extends into the opening 178 are within the scope of the present disclosure.

FIG. 1E illustrates an alternative implementation of the via portion 180 of the bonding structure 146b in which the via portion 180 of the bonding structure 146b extends through the opening 178 in the top portion 176 of the metal pad structure 144b and into a portion of the bottom portion 174 of the metal pad structure 144b. In other words, the depth to which the via portion 180 of the bonding structure 146b extends into the opening 178 is greater than the z-direction thickness of the top portion 176 of the metal pad structure 144b (e.g., dimension D8>dimension D7), but is still less than the combined z-direction thickness of the bottom portion 174 and the top portion 176 of the metal pad structure 144b (e.g., dimension D8<dimension D7 plus the thickness of the passivation layer 138b). In some implementations, the via portion 180 of the bonding structure 146b may be formed to extend through the opening 178 in the top portion 176 of the metal pad structure 144b and into a portion of the bottom portion 174 of the metal pad structure 144b to ensure that any voids in the passivation layer 138b within the opening 178 are fully opened and filled in with the via portion 180.

As indicated above, FIGS. 1A-1E are provided as an example. Other examples may differ from what is described with regard to FIGS. 1A-1E.

FIGS. 2A-2I are diagrams of examples of top view layouts for seal ring structures in a semiconductor die package described herein. While the examples of top view layouts for seal ring structures are illustrated in connection with the semiconductor die package 102 in FIGS. 2A-2I, the examples of top view layouts for seal ring structures may be implemented in other semiconductor die packages, including a semiconductor die package 702 described in connection with FIGS. 7A-7E, among other examples. FIGS. 2A-2I also illustrate the location of the cross-section views along the line A-A illustrated herein.

FIG. 2A illustrates an example 200 of a top view layout for seal ring structures 136a and 136b, respectively, of the IC dies 104 and 106. As shown in FIG. 2A, the seal ring structure 136a in the IC die 104 includes a continuous closed-looped structure laterally surrounding the perimeter (e.g., around the perimeter) of the IC die 104. Above the seal ring structure 136a is the metal pad structure 144a, which may also include a continuous closed-looped structure around the perimeter of the IC die 104. Above the metal pad structure 144a is the bonding structure 146a, which may also include a continuous closed-looped structure laterally surrounding (e.g., around the perimeter) of the IC die 104. The metal pad structure 144a may conform to the top view layout of the seal ring structure 136a. The bonding structure 146a may conform to the top view layout of the metal pad structure 144a.

Similarly, the seal ring structure 136b in the IC die 106 includes a continuous closed-looped structure laterally surrounding (e.g., around the perimeter) of the IC die 106. Below the seal ring structure 136b is the metal pad structure 144b, which may also include a continuous closed-looped structure laterally surrounding (e.g., around the perimeter) of the IC die 106. Below the metal pad structure 144b is the bonding structure 146b, which may also include a continuous closed-looped structure laterally surrounding (e.g., around the perimeter) of the IC die 106. The metal pad structure 144b may conform to the top view layout of the seal ring structure 136b. The bonding structure 146b may conform to the top view layout of the metal pad structure 144b.

FIG. 2B illustrates an example 202 of a top view layout for seal ring structures 136a and 136b, respectively, of the IC dies 104 and 106. As shown in FIG. 2B, the example 202 is similar to the example 200, except that the bonding structure 146a of the IC die 104 includes a plurality of discontinuous segments above the metal pad structure 144a and laterally surrounding (e.g., around the perimeter) of the IC die 104. Including a continuous closed-looped structure laterally surrounding (e.g., around the perimeter) of the IC die 104 for the bonding structure 146a may improve the stiffness of the IC die 104 and/or may increase the protection against ingress of humidity and other contaminants in the IC die 104, whereas including a plurality of discontinuous segments for the bonding structure 146a enables the quantity, size, shape, and/or arrangement of the plurality of discontinuous segments to be tuned to reduce die edge stress in the IC die 104, which may reduce the likelihood and/or amount of warpage in the IC die 104.

FIG. 2C illustrates an example 204 of a top view layout for seal ring structures 136a and 136b, respectively, of the IC dies 104 and 106. As shown in FIG. 2C, the example 204 is similar to the example 200, except that the bonding structure 146b of the IC die 106 includes a plurality of discontinuous segments below the metal pad structure 144b and laterally surrounding (e.g., around the perimeter) of the IC die 106. Including a continuous closed-looped structure laterally surrounding (e.g., around the perimeter) of the IC die 104 for the bonding structure 146b may improve the stiffness of the IC die 104 and/or may increase the protection against ingress of humidity and other contaminants in the IC die 104, whereas including a plurality of discontinuous segments for the bonding structure 146b enables the quantity, size, shape, and/or arrangement of the plurality of discontinuous segments to be tuned to reduce die edge stress in the IC die 106, which may reduce the likelihood and/or amount of warpage in the IC die 106.

FIG. 2D illustrates an example 206 of a top view layout for seal ring structures 136a and 136b, respectively, of the IC dies 104 and 106. As shown in FIG. 2D, the example 206 is similar to the example 200, except that the bonding structure 146a of the IC die 104 includes a plurality of discontinuous segments above the metal pad structure 144a and laterally surrounding (e.g., around the perimeter) of the IC die 104, and the bonding structure 146b of the IC die 106 includes a plurality of discontinuous segments below the metal pad structure 144b and laterally surrounding (e.g., around the perimeter) of the IC die 106.

FIG. 2E illustrates an example 208 of a top view layout for seal ring structures 136a and 136b, respectively, of the IC dies 104 and 106. As shown in FIG. 2E, the example 208 is similar to the example 202, except that, in addition to the bonding structure 146a of the IC die 104 including a plurality of discontinuous segments above the metal pad structure 144a and laterally surrounding (e.g., around the perimeter) of the IC die 104, the metal pad structure 144a of the IC die 104 also includes a plurality of discontinuous segments above the seal ring structure 136a and laterally surrounding (e.g., around the perimeter) of the IC die 104. Including a continuous closed-looped structure laterally surrounding (e.g., around the perimeter) of the IC die 104 for the metal pad structure 144a may improve the stiffness of the IC die 104 and/or may increase the protection against ingress of humidity and other contaminants in the IC die 104, whereas including a plurality of discontinuous segments for the metal pad structure 144a enables the quantity, size, shape, and/or arrangement of the plurality of discontinuous segments to be tuned to reduce die edge stress in the IC die 104, which may reduce the likelihood and/or amount of warpage in the IC die 104.

FIG. 2F illustrates an example 210 of a top view layout for seal ring structures 136a and 136b, respectively, of the IC dies 104 and 106. As shown in FIG. 2F, the example 210 is similar to the example 204, except that, in addition to the bonding structure 146b of the IC die 106 including a plurality of discontinuous segments above the metal pad structure 144b and laterally surrounding (e.g., around the perimeter) of the IC die 106, the metal pad structure 144b of the IC die 106 also includes a plurality of discontinuous segments above the seal ring structure 136b and laterally surrounding (e.g., around the perimeter) of the IC die 106. Including a continuous closed-looped structure laterally surrounding (e.g., around the perimeter) of the IC die 106 for the metal pad structure 144b may improve the stiffness of the IC die 106 and/or may increase the protection against ingress of humidity and other contaminants in the IC die 106, whereas including a plurality of discontinuous segments for the metal pad structure 144b enables the quantity, size, shape, and/or arrangement of the plurality of discontinuous segments to be tuned to reduce die edge stress in the IC die 106, which may reduce the likelihood and/or amount of warpage in the IC die 106.

FIG. 2G illustrates an example 212 of a top view layout for seal ring structures 136a and 136b, respectively, of the IC dies 104 and 106. As shown in FIG. 2G, the example 212 is similar to the examples 208 and 210. However, in the example 212, the IC die 104 includes respective pluralities of discontinuous segments for each of the metal pad structure 144a and the bonding structure 146a, and the IC die 106 includes respective pluralities of discontinuous segments for each of the metal pad structure 144b and the bonding structure 146b.

FIG. 2H illustrates an example 214 of a top view layout for seal ring structures 136a and 136b, respectively, of the IC dies 104 and 106. As shown in FIG. 2H, the example 214 is similar to the example 200, except that the IC die 104 includes dual seal ring structures 136a-1 and 136a-2, as opposed to a single seal ring structure 136a. Each seal ring structure 136a-1 and 136a-2 may include a continuous closed-loop structure laterally surrounding (e.g., around the perimeter) of the IC die 104, where the seal ring structure 136a-1 is an outer seal ring structure of the IC die 104 and the seal ring structure 136a-2 is an inner seal ring structure of the IC die 104. Including a plurality of seal ring structures 136a around the IC die 104 may provide increased structural rigidity for the IC die 104 and/or may provide increased protection against ingress of humidity and other contaminants.

Respective metal pad structures 144a may be included above each seal ring structure 136a-1 and 136a-2, and respective bonding structures 146a may be included above each of the metal pad structures 144a. The metal pad structures 144a and the bonding structures 146a above the seal ring structures 136a-1 and 136a-2 may be arranged in one or more of the top view layouts illustrated in FIGS. 2A-2G and/or in another top view arrangement. In some implementations, the metal pad structures 144a above the seal ring structures 136a-1 and 136a-2 have the same top view layout. In some implementations, the metal pad structures 144a above the seal ring structures 136a-1 and 136a-2 have different top view layouts. In some implementations, the bonding structures 146a above the seal ring structures 136a-1 and 136a-2 have the same top view layout. In some implementations, the bonding structures 146a above the seal ring structures 136a-1 and 136a-2 have different top view layouts.

FIG. 2I illustrates an example 216 of a top view layout for seal ring structures 136a and 136b, respectively, of the IC dies 104 and 106. As shown in FIG. 2I, the example 216 is similar to the example 214, except that the IC die 106 includes dual seal ring structures 136b-1 and 136b-2 as opposed to a single seal ring structure 136b. Each seal ring structure 136b-1 and 136b-2 may include a continuous closed-loop structure laterally surrounding (e.g., around the perimeter) of the IC die 106, where the seal ring structure 136b-1 is an outer seal ring structure of the IC die 106 and the seal ring structure 136b-2 is an inner seal ring structure of the IC die 106. Including a plurality of seal ring structures 136b around the IC die 106 may provide increased structural rigidity for the IC die 106 and/or may provide increased protection against ingress of humidity and other contaminants.

Respective metal pad structures 144b may be included above each seal ring structure 136b-1 and 136b-2, and respective bonding structures 146b may be included above each of the metal pad structures 144b. The metal pad structures 144b and the bonding structures 146b above the seal ring structures 136b-1 and 136b-2 may be arranged in one or more of the top view layouts illustrated in FIGS. 2A-2G and/or in another top view arrangement. In some implementations, the metal pad structures 144b above the seal ring structures 136b-1 and 136b-2 have the same top view layout. In some implementations, the metal pad structures 144b above the seal ring structures 136b-1 and 136b-2 have different top view layouts. In some implementations, the bonding structures 146b above the seal ring structures 136b-1 and 136b-2 have the same top view layout. In some implementations, the bonding structures 146b above the seal ring structures 136b-1 and 136b-2 have different top view layouts.

As indicated above, FIGS. 2A-2I are provided as examples. Other examples may differ from what is described with regard to FIGS. 2A-2I.

FIGS. 3A-3E are diagrams of an example implementation 300 of forming a portion of an IC die described herein. While the processing operations of the example implementation 300 are illustrated and described in connection with forming the IC die 104 described herein, the processing operations of the example implementation 300 may be performed to form another IC die described herein, such as an IC die 106, an IC die 704 of FIGS. 7A-7E, and/or an IC die 706 of FIGS. 7A-7E, among other examples. In some implementations, one or more of the semiconductor processing operations described in connection with FIGS. 3A-3E may be performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

Turning to FIG. 3A, the substrate 122a of the IC die 104 is provided. The substrate 122a may be provided in the form of a semiconductor wafer such as a silicon (Si) wafer, may be provided as an SOI wafer, and/or another type of semiconductor work piece.

As shown in FIG. 3B, the IC devices 126a may be formed in and/or on the substrate 122a. One or more semiconductor processing tools may be used to form one or more portions of the IC devices 126a. For example, a deposition tool may be used to perform various deposition operations to deposit layers and/or structures of the IC devices 126a, and/or to deposit photoresist layers for etching the substrate 122a and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 122a and/or portions of the deposited layers to form the IC devices 126a. As another example, a planarization tool may be used to planarize portions of the IC devices 126a. As another example, a plating tool may be used to deposit metal structures and/or layers of the IC devices 126a.

As further shown in FIG. 3B, a deposition tool is used to deposit the ILD layer 124a over and/or on the substrate 122a and over and/or on the IC devices 126a. A deposition tool may be used to deposit the ILD layer 124a using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the ILD layer 124a after the ILD layer 124a is deposited.

As shown in FIG. 3C, the contacts 128a of the IC devices 126a may be formed through the ILD layer 124a. The contacts 128a may be formed in recesses in the ILD layer 124a. In some implementations, a pattern in a photoresist layer is used to etch the ILD layer 124a to form the recesses. In these implementations, a deposition tool may be used to form the photoresist layer on the ILD layer 124a. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layer 124a based on a pattern to form the recesses.

A deposition tool may be used to deposit the material of the contacts 128a in the recesses using a CVD technique, a PVD technique, an ALD technique, an electroplating technique, and/or another suitable deposition technique. The material of the contacts 128a may be deposited in one or more deposition operations. In some implementations, a seed layer is first deposited, and the material of the contacts 128a is deposited on the seed layer. In some implementations, a planarization tool is used to perform a planarization operation (e.g., a CMP operation) to planarize the contacts 128a after the contacts 128a are deposited such that the tops of the contacts 128a are approximately co-planar with the top of the ILD layer 124a.

As shown in FIG. 3C, a first portion of the interconnect layer of the IC die 104 is formed above the ILD layer 124a. One or more deposition tools are used to deposit alternating layers of ILD layers 130a and ESLs 132a in the first portion of the interconnect layer of the IC die 104. In this way, the ILD layers 130a and ESLs 132a may be arranged in the z-direction in the IC die 104. One or more deposition tools may be used to deposit each of the ILD layers 130a and each of the ESLs 132a using a PVD technique, an ALD technique, a CVD technique, an oxidation technique, and/or another suitable deposition technique. In some implementations, a planarization tool may be used to planarize the ILD layers 130a and/or the ESLs 132a after the ILD layers 130a and/or the ESLs 132a are deposited.

As further shown in FIG. 3C, a deposition tool, an exposure tool, a developer tool, an etch tool, a planarization tool, a plating tool, and/or another semiconductor processing tool may be used to perform various operations to form the conductive structures 134a and a first portion of the seal ring structure 136a in the first portion of the interconnect layer of the IC die 104. The conductive structures 134a and the first portion of the seal ring structure 136a may be included in the ILD layers 130a and/or the ESLs 132a.

The conductive structures 134a and the first portion of the seal ring structure 136a may be formed in recesses in one or more ILD layers 130a and/or in one or more ESLs 132a. In some implementations, a pattern in a photoresist layer is used to etch the ILD layers 130a and ESLs 132a to form the recesses. In these implementations, a deposition tool may be used to form the photoresist layer on the topmost ILD layer 130a. An exposure tool may be used to expose the photoresist layer to a radiation source to pattern the photoresist layer. A developer tool may be used to develop and remove portions of the photoresist layer to expose the pattern. An etch tool may be used to etch the ILD layers 130a and ESLs 132a based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layers 130a and ESLs 132a based on a pattern to form the recesses.

A deposition tool may be used to deposit the material of the conductive structures 134a and the first portion of the seal ring structure 136a in the recesses using a CVD technique, a PVD technique, an ALD technique, an electroplating technique, and/or another suitable deposition technique. The material of the conductive structures 134a and the first portion of the seal ring structure 136a may be deposited in one or more deposition operations. In some implementations, a seed layer is first deposited, and the material of the conductive structures 134a and the first portion of the seal ring structure 136a is deposited on the seed layer. In some implementations, a planarization tool is used to perform a planarization operation (e.g., a CMP operation) to planarize the conductive structures 134a and the first portion of the seal ring structure 136a.

As shown in FIG. 3D, the die-to-die interconnect 152 is formed through the first portion of the interconnect layer and into the substrate 122a. To form the die-to-die interconnect 152, a recess is formed through the first portion of the interconnect layer and into a portion of the substrate 122a. In some implementations, a pattern in a photoresist layer is used to etch the ILD layers 130a and the ESLs 132a of the first portion of the interconnect layer, the ILD layer 124a, and the substrate 122a to form the recess. In these implementations, a deposition tool may be used to form the photoresist layer on the topmost ILD layer 130a. An exposure tool may be used to expose the photoresist layer to a radiation source to pattern the photoresist layer. A developer tool may be used to develop and remove portions of the photoresist layer to expose the pattern. An etch tool may be used to etch the ILD layers 130a and the ESLs 132a of the first portion of the interconnect layer, the ILD layer 124a, and the substrate 122a based on the pattern to form the recess. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess based on a pattern.

A deposition tool may be used to deposit the die-to-die interconnect 152 using a CVD technique, a PVD technique, an ALD technique, an electroplating technique, and/or another suitable deposition technique. The die-to-die interconnect 152 may be deposited in one or more deposition operations. In some implementations, a seed layer is first deposited, and the die-to-die interconnect 152 is deposited on the seed layer. In some implementations, one or more liners (e.g., a barrier liner, an adhesion liner) may first be deposited in the recess, and the die-to-die interconnect 152 may be deposited on the one or more liners in the recess. In some implementations, a planarization tool is used to perform a planarization operation (e.g., a CMP operation) to planarize the die-to-die interconnect 152 after the die-to-die interconnect 152 is deposited.

As shown in FIG. 3E, a second portion of the interconnect layer of the IC die 104 may be formed. Forming the second portion of the interconnect layer may include forming additional ILD layers 130a, additional ESLs 132a, additional conductive structures 134a, and/or additional portions of the seal ring structure 136a in a similar manner as described in connection with FIG. 3C. As further shown in FIG. 3E, the passivation layer 138a may be deposited, the metal pad structures 142a may be formed on one or more of the conductive structures 134a, and one or more metal pad structures 144a may be formed on the seal ring structure 136a.

As indicated above, FIGS. 3A-3E are provided as an example. Other examples may differ from what is described with regard to FIGS. 3A-3E. In some implementations, the layers and/or structures of the IC die 106 (or a portion thereof) may be formed using similar processes and/or techniques as described in connection with FIGS. 3A-3E.

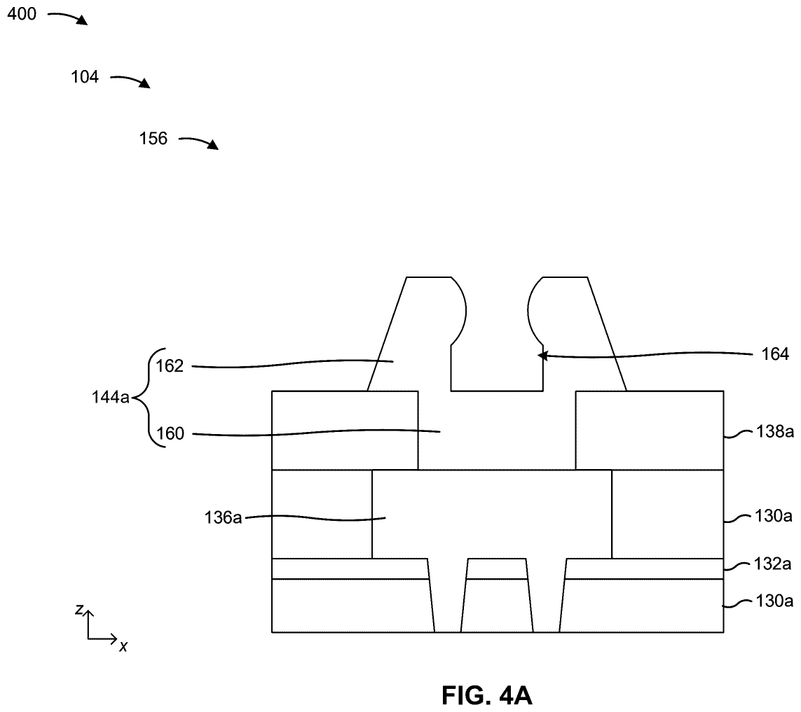

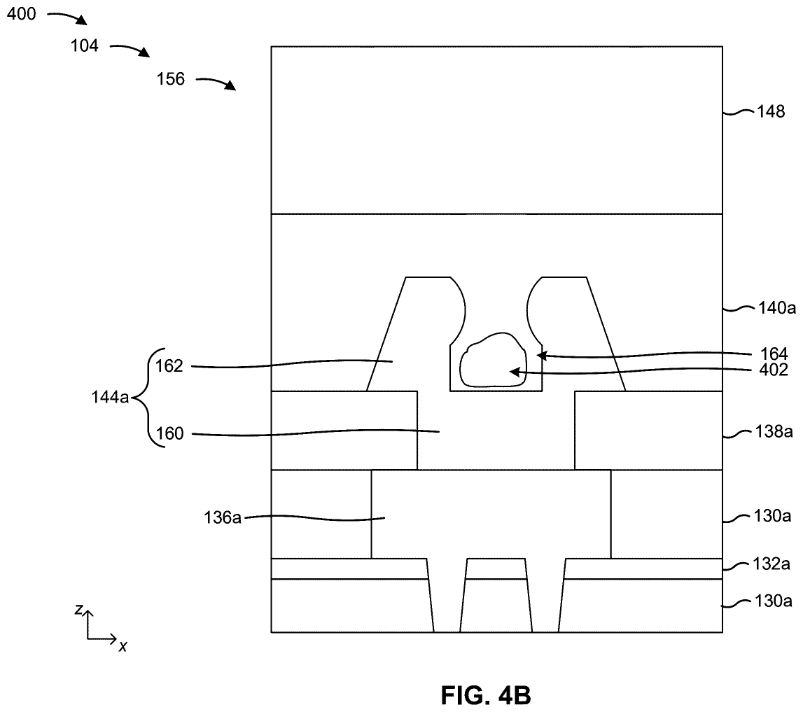

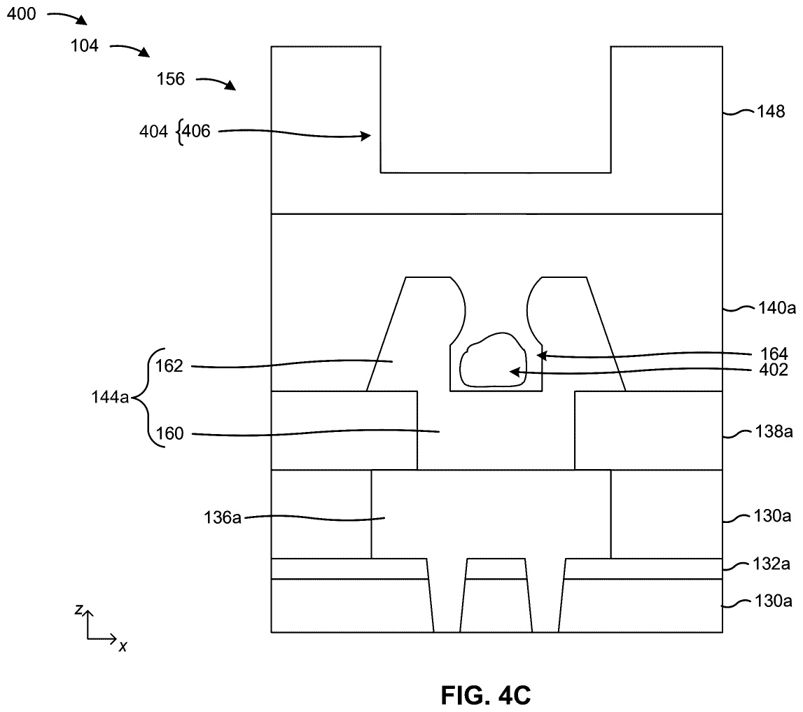

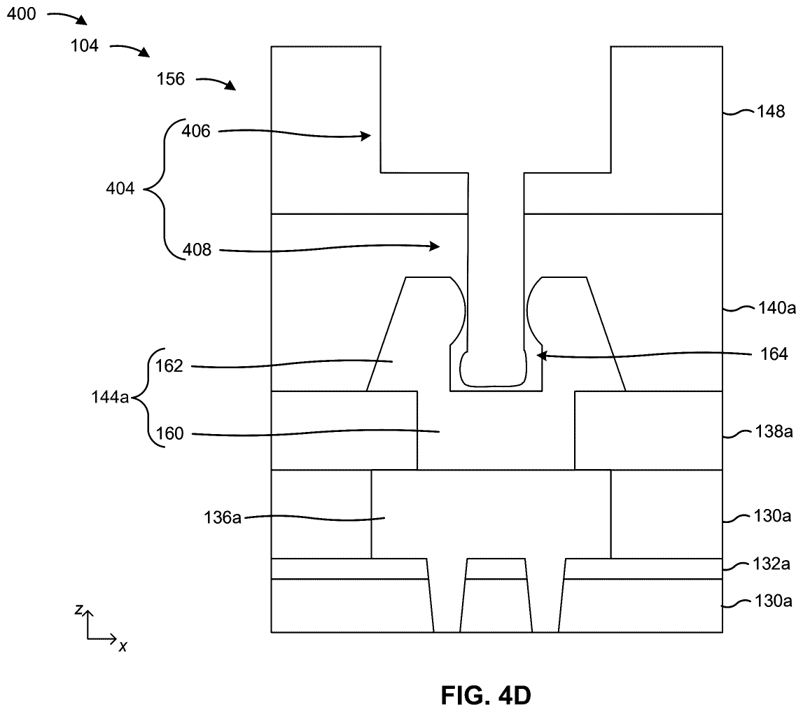

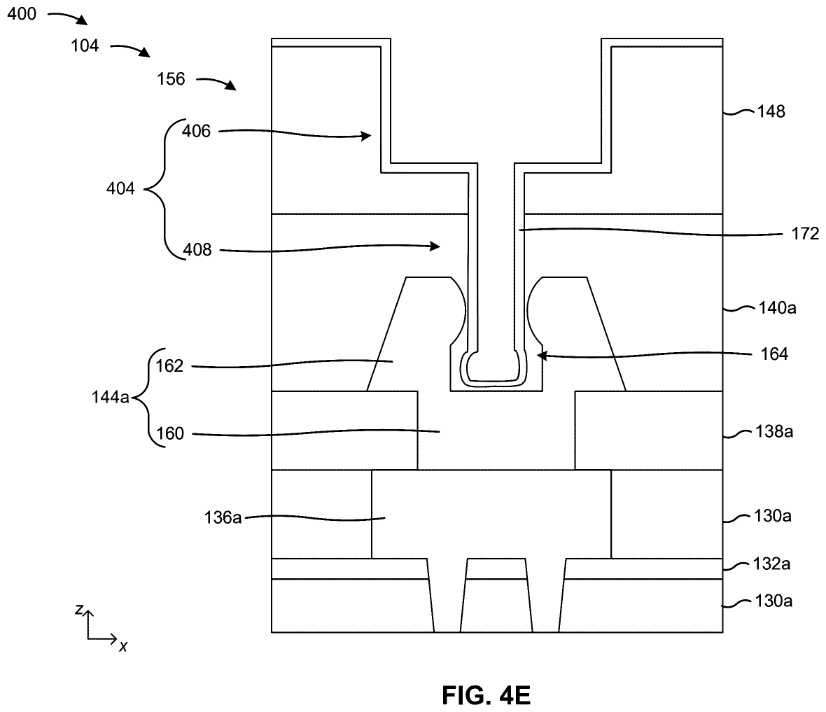

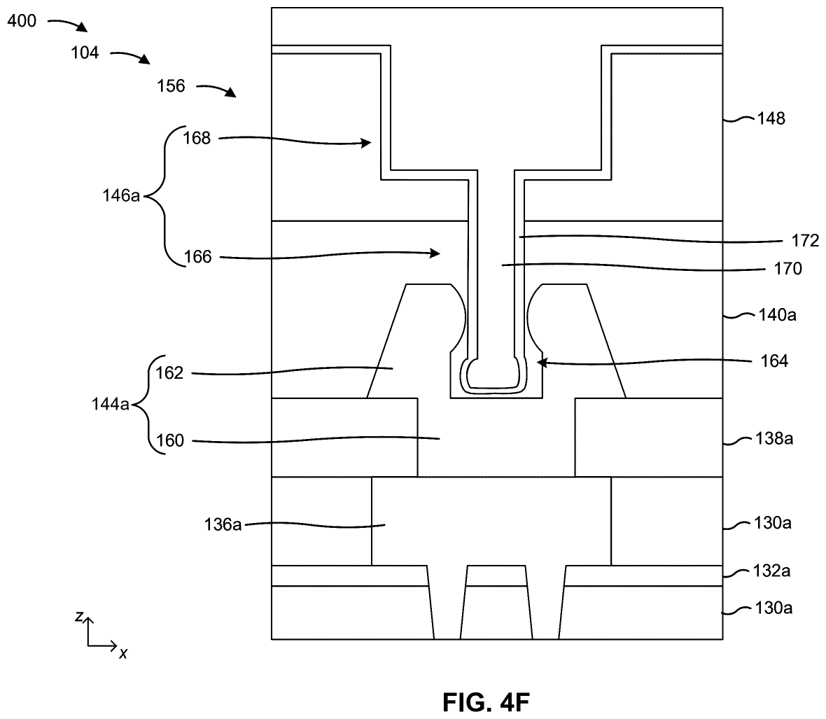

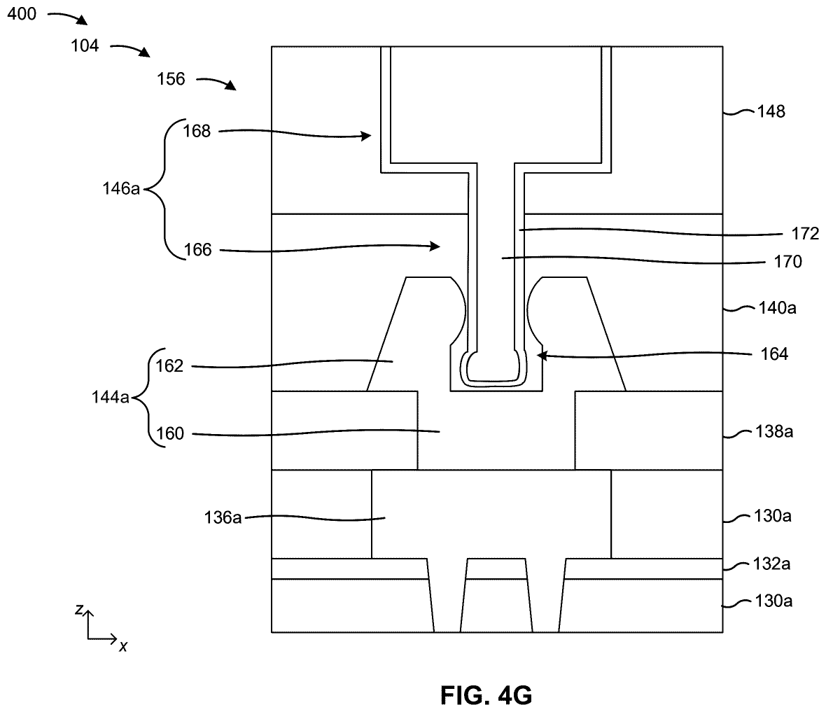

FIGS. 4A-4G are diagrams of an example implementation 400 of forming a portion of an IC die described herein. While the processing operations of the example implementation 400 are illustrated and described in connection with forming the IC die 104 described herein, the processing operations of the example implementation 400 may be performed to form another IC die described herein, such as an IC die 106, an IC die 704 of FIGS. 7A-7E, and/or an IC die 706 of FIGS. 7A-7E, among other examples. In some implementations, one or more of the semiconductor processing operations described in connection with FIGS. 4A-4G may be performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 4A, a metal pad structure 144a may be formed on the topmost conductive structure of the seal ring structure 136a of the IC die 104. The metal pad structure 144a may be formed such that a bottom portion 160 of the metal pad structure 144a extends through the passivation layer 138a and is in contact with a top surface of the topmost conductive structure of the seal ring structure 136a. Moreover, the metal pad structure 144a may be formed such that a top portion 162 of the metal pad structure 144a is formed above and/or on the passivation layer 138a.

In some implementations, a pattern in a photoresist layer is used to etch the passivation layer 138a to form the recess in the passivation layer 138a. In these implementations, a deposition tool may be used to form the photoresist layer on the passivation layer 138a. An exposure tool may be used to expose the photoresist layer to a radiation source to pattern the photoresist layer. A developer tool may be used to develop and remove portions of the photoresist layer to expose the pattern. An etch tool may be used to etch the passivation layer 138a based on the pattern to form the recess. The recess extends through the passivation layer 138a such that the top surface of the topmost conductive structure of the seal ring structure 136a is exposed through the recess. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the passivation layer 138a based on a pattern.

A deposition tool may be used to deposit the material of the metal pad structure 144a using a CVD technique, a PVD technique, an ALD technique, and/or another suitable deposition technique. The metal pad structure 144a may be deposited in one or more deposition operations. The metal pad structure 144a may be formed such that the bottom portion 160 of the metal pad structure 144a is deposited in the recess in the passivation layer 138a, and such that the top portion 162 extends above the passivation layer 138a. As shown in FIG. 4A, the top portion 162 that extends above the recess in the passivation layer 138a may not fully coalesce, resulting in an opening 164 being formed in the top portion 162.

As shown in FIG. 4B, the passivation layer 140a is formed above the passivation layer 138a such the metal pad structure 144a is covered by the passivation layer 140a. A deposition tool may be used to deposit the passivation layer 140a using a PVD technique, a CVD technique (e.g., low-pressure CVD (LPCVD), plasma-enhanced CVD (PECVD), high density plasma (HDP) CVD), an oxidation technique, and/or another suitable deposition technique. In some implementations, a planarization tool may be used to perform a planarization operation such as a CMP operation to planarize the passivation layer 140a after the passivation layer 140a is deposited.

As further shown in FIG. 4B, in some cases, a void 402 may form in a portion of the passivation layer 140a that is located within the opening 164 of the metal pad structure 144a. The void 402 may form due to various factors, including the step coverage of the deposition technique used to deposit the passivation layer 140a and/or the size of the opening 164 in the top portion 162 of the metal pad structure 144a, among other examples.

As further shown in FIG. 4B, the bonding layer 148 is formed above and/or on the passivation layer 140a. A deposition tool may be used to deposit the bonding layer 148 using a PVD technique, a CVD technique, an oxidation technique, and/or another suitable deposition technique. In some implementations, a planarization tool may be used to perform a planarization operation such as a CMP operation to planarize the bonding layer 148 after the bonding layer 148 is deposited.

As shown in FIGS. 4C and 4D, a recess 404 is formed through the bonding layer 148 and into the passivation layer 140a such that the recess 404 extends into the opening 164 of the top portion 162 of the metal pad structure 144a. The formation of the recess 404 opens up the void 402 within the opening 164 in the top portion 162 of the metal pad structure 144a, thereby enabling the void 402 to be filled in with material to reduce or minimize the likelihood that the void 402 might otherwise cause delamination to occur in the passivation layer 140a and/or in the bonding layer 148. As shown in FIGS. 4C and 4D, the recess 404 may be formed as a dual damascene recess having a trench portion 406 and a via portion 408. While FIGS. 4C and 4D illustrate a trench-first process in which the trench portion 406 of the recess 404 is formed prior to formation of the via portion 408, a via-first process may alternatively be performed to form the recess 404.

As shown in FIG. 4C, the trench portion 406 of the recess 404 is formed in the bonding layer 148. The trench portion 406 of the recess 404 is formed such that the trench portion 406 of the recess 404 is located over the metal pad structure 144a. In some implementations, a pattern in a photoresist layer is used to etch the bonding layer 148 to form the trench portion 406 of the recess 404. In these implementations, a deposition tool may be used to form the photoresist layer on the bonding layer 148. An exposure tool may be used to expose the photoresist layer to a radiation source to pattern the photoresist layer. A developer tool may be used to develop and remove portions of the photoresist layer to expose the pattern. An etch tool may be used to etch the bonding layer 148 based on the pattern to form the trench portion 406 of the recess 404. Alternatively, the pattern in the photoresist layer may be used to transfer the pattern to a hard mask layer, and the pattern in the hard mask layer is used to etch the bonding layer 148 to form the trench portion 406 of the recess 404. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique).

As shown in FIG. 4D, the via portion 408 of the recess 404 is formed through the bottom of the trench portion 406, through the bonding layer 148, into the passivation layer 140a, and into the opening 164 in the top portion 162 of the metal pad structure 144a. Thus, the via portion 408 extends into the opening 164 in the top portion 162 of the metal pad structure 144a such that the void 402 in the opening 164 is opened through the via portion 408 of the recess 404.

In some implementations, a pattern in a photoresist layer is used to etch the bonding layer 148 and/or the passivation layer 140a to form the via portion 408 of the recess 404. In these implementations, a deposition tool may be used to form the photoresist layer on the bonding layer 148 and in the trench portion 406 of the recess 404. An exposure tool may be used to expose the photoresist layer to a radiation source to pattern the photoresist layer. A developer tool may be used to develop and remove portions of the photoresist layer to expose the pattern. An etch tool may be used to etch the bonding layer 148 and/or the passivation layer 140a based on the pattern to form the via portion 408 of the recess 404. Alternatively, the pattern in the photoresist layer may be used to transfer the pattern to a hard mask layer, and the pattern in the hard mask layer is used to etch the bonding layer 148 and/or the passivation layer 140a to form the via portion 408 of the recess 404. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique).

As shown in FIG. 4E, the liner 172 of the bonding structure 146a is formed on the sidewalls of the trench portion 406 and on the sidewalls of the via portion 408 of the recess 404. In some implementations, the liner 172 is also formed on the bottom portions of the trench portion 406 of the recess 404, and on the bottom surface of the via portion 408 of the recess 404. In some implementations, the liner 172 is also formed on the top surface of the bonding layer 148. The liner 172 may be conformally deposited in the recess 404 using a conformal deposition technique such as CVD and/or ALD, among other examples.

As shown in FIG. 4F, the trench portion 406 and the via portion 408 of the recess 404 are filled with the metal layer 170 of the bonding structure 146a. The metal layer 170 is deposited on the liner 172 in the recess 404. The portion of metal layer 170 that fills in the via portion 408 corresponds to the via portion 166 of the bonding structure 146a, and the portion of metal layer 170 that fills in the trench portion 406 corresponds to the trench portion 168 of the bonding structure 146a. The metal layer 170 of the bonding structure 146a extends into the opening 164 within the top portion 162 of the metal pad structure 144a, thereby filling in any voids that may have formed in the passivation layer 140a within the opening 164. In some implementations, the recess 404 may be overfilled with the material of the metal layer 170 to ensure that the recess 404 is filled in a void-free manner.

A deposition tool may be used to deposit the metal layer 170 using a CVD technique, a PVD technique, an ALD technique, an electroplating technique, and/or another suitable deposition technique. The metal layer 170 may be deposited in one or more deposition operations. In some implementations, a seed layer is first deposited, and the metal layer 170 is deposited on the seed layer.

As shown in FIG. 4G, a planarization tool is used to perform a planarization operation (e.g., a CMP operation) to planarize the bonding structure 146a after the bonding structure 146a is deposited. The planarization operation removes excess material from the metal layer 170 and excess material from the liner 172 that was deposited on the top of the bonding layer 148.

As indicated above, FIGS. 4A-4G are provided as an example. Other examples may differ from what is described with regard to FIGS. 4A-4G. In some implementations, the layers and/or structures of the IC die 106 (or a portion thereof) may be formed using similar processes and/or techniques as described in connection with FIGS. 4A-4G.

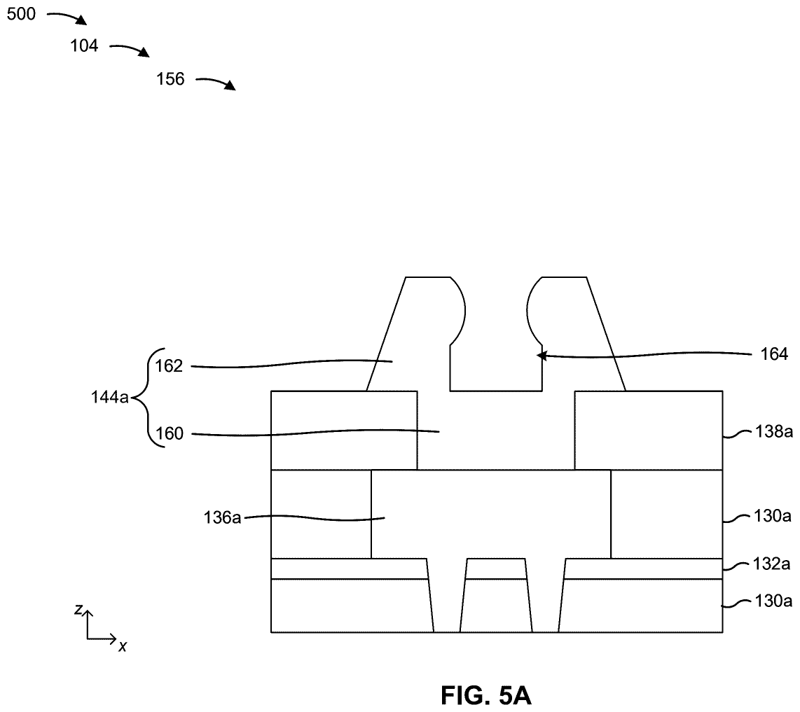

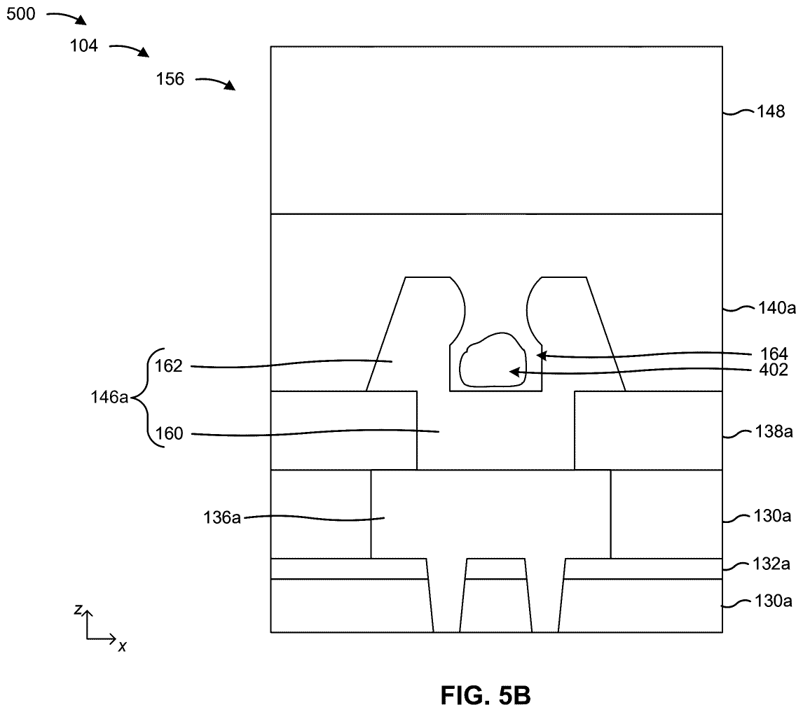

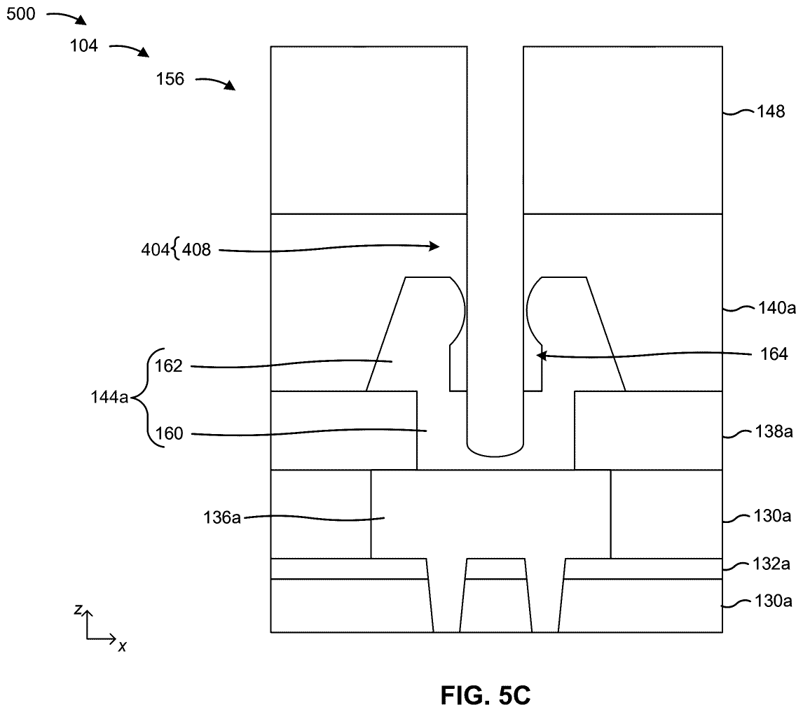

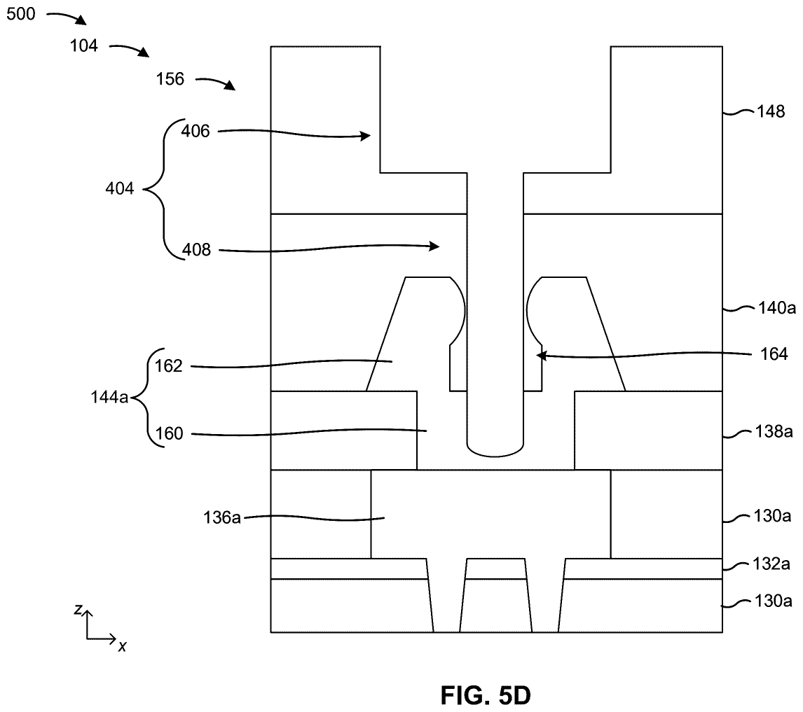

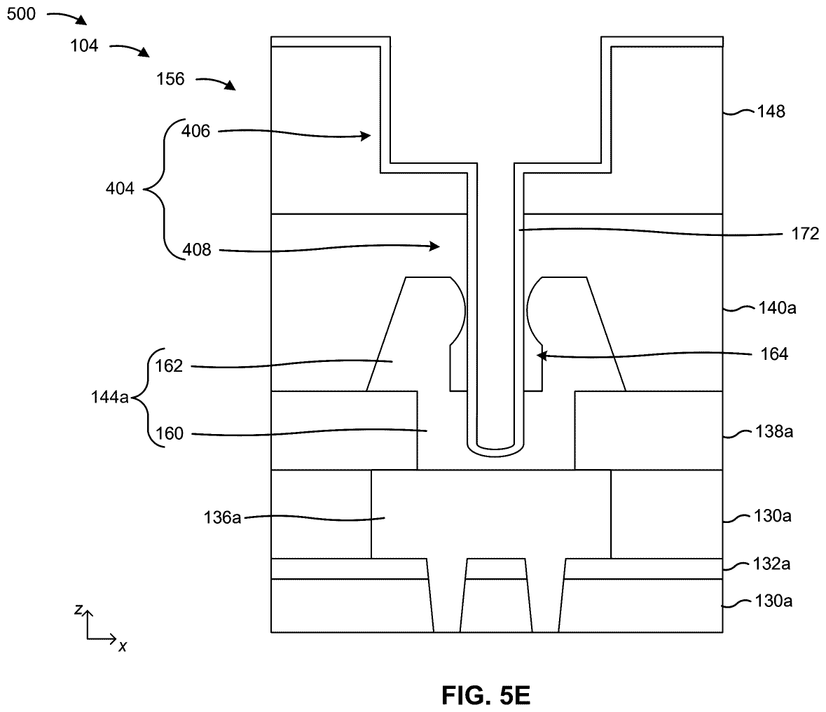

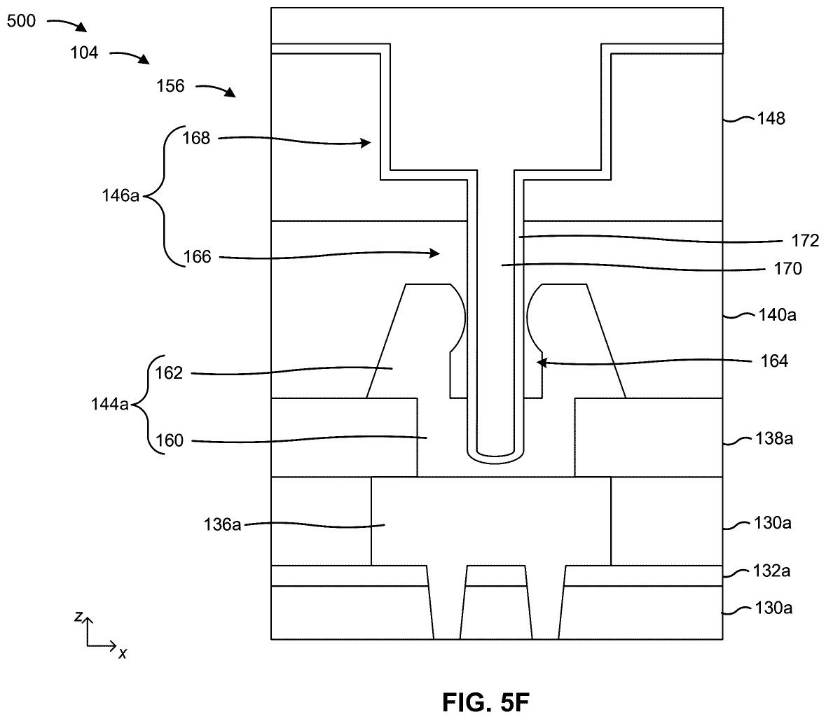

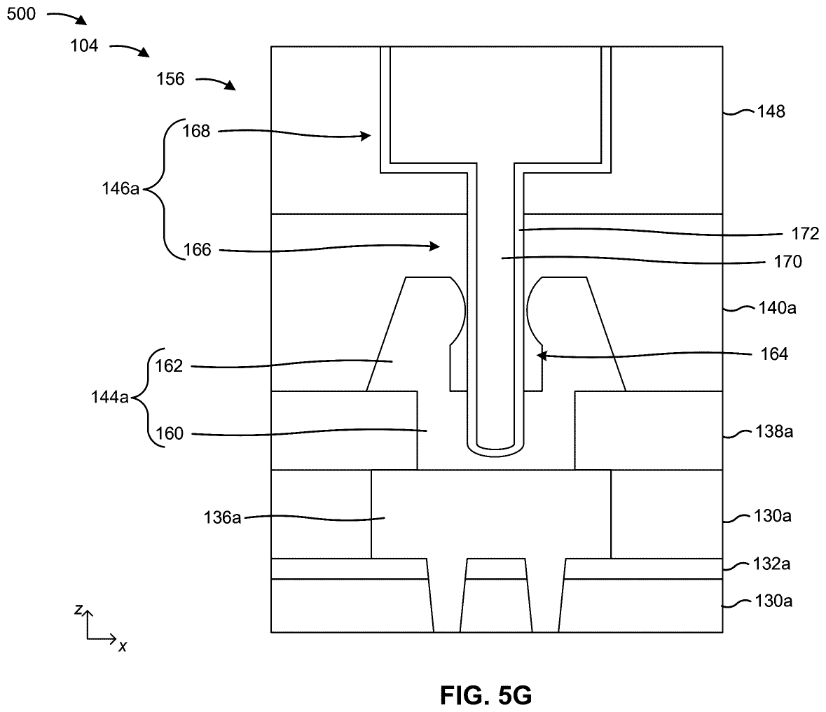

FIGS. 5A-5G are diagrams of an example implementation 500 of forming a portion of an IC die described herein. While the processing operations of the example implementation 500 are illustrated and described in connection with forming the semiconductor die package 102 described herein, the processing operations of the example implementation 500 may be performed to form another semiconductor device described herein, such as a semiconductor die package 702 of FIGS. 7A-7E, among other examples. In some implementations, one or more of the semiconductor processing operations described in connection with FIGS. 5A-5G may be performed using one or more semiconductor processing tools, such as a deposition tool, an exposure tool, a developer tool, an etch tool, a planarization tool, a wafer/die transport tool, and/or another type of semiconductor processing tool.

As shown in FIG. 5A, a metal pad structure 144a may be formed on the topmost conductive structure of the seal ring structure 136a of the IC die 104 in a similar manner as described in connection with FIG. 4A. As shown in FIG. 5B, the passivation layer 140a is formed above the passivation layer 138a in a similar manner as described in connection with FIG. 4B. As further shown in FIG. 5B, the bonding layer 148 is formed above and/or on the passivation layer 140a in a similar manner as described in connection with FIG. 4B.

As shown in FIGS. 5C and 5D, the recess 404 is formed through the bonding layer 148 and into the passivation layer 140a in a similar manner as described above in connection with FIGS. 4C and 4D. However, FIGS. 5C and 5D illustrate a via-first process for forming the recess 404. Moreover, in the example implementation 500, the recess 404 is formed such that the recess 404 extends through the opening 164 of the top portion 162 of the metal pad structure 144a and into the bottom portion 160 of the metal pad structure 144a. The formation of the recess 404 through the opening 164 of the top portion 162 of the metal pad structure 144a and into the bottom portion 160 of the metal pad structure 144a opens up voids 402 within the opening 164 in the top portion 162 of the metal pad structure 144a, thereby enabling the voids 402 to be filled in with material to reduce or minimize the likelihood that the voids 402 might otherwise cause delamination to occur in the passivation layer 140a and/or in the bonding layer 148.

As shown in FIG. 5C, the via portion 408 of the recess 404 is formed through the opening 164 of the top portion 162 of the metal pad structure 144a and into the bottom portion 160 of the metal pad structure 144a. As shown in FIG. 5D, the trench portion 406 of the recess 404 is formed in the bonding layer 148 after formation of the via portion 408. Alternatively, a trench-first process may be performed to form the recess 404, in which the trench portion 406 is formed prior to the via portion 408.

As shown in FIG. 5E, the liner 172 of the bonding structure 146a is formed in the recess 404 in a similar manner as described in connection with FIG. 4E. However, since the via portion 408 of the recess 404 extends into the bottom portion 160 of the metal pad structure 144a, the liner 172 is formed on the sidewalls and the bottom surface at the bottom of the via portion 408 of the recess 404 corresponding to the bottom portion 160 of the metal pad structure 144a.

As shown in FIG. 5F, the trench portion 406 and the via portion 408 of the recess 404 are filled with the metal layer 170 of the bonding structure 146a in a similar manner as described in connection with FIG. 4F. However, in the example implementation 500, the portion of metal layer 170 that fills in the via portion 408 extends through the opening 164 in the top portion 162 of the metal pad structure 144a and into the bottom portion 160 of the metal pad structure 144a. Thus, the via portion 166 of the bonding structure 146a extends through the opening 164 in the top portion 162 of the metal pad structure 144a and into the bottom portion 160 of the metal pad structure 144a.

As shown in FIG. 5G, a planarization tool is used to perform a planarization operation (e.g., a CMP operation) to planarize the bonding structure 146a after the bonding structure 146a is deposited. The planarization operation removes excess material from the metal layer 170 and excess material from the liner 172 that was deposited on the top of the bonding layer 148.

As indicated above, FIGS. 5A-5G are provided as an example. Other examples may differ from what is described with regard to FIGS. 5A-5G. In some implementations, the layers and/or structures of the IC die 106 (or a portion thereof) may be formed using similar processes and/or techniques as described in connection with FIGS. 5A-5G.

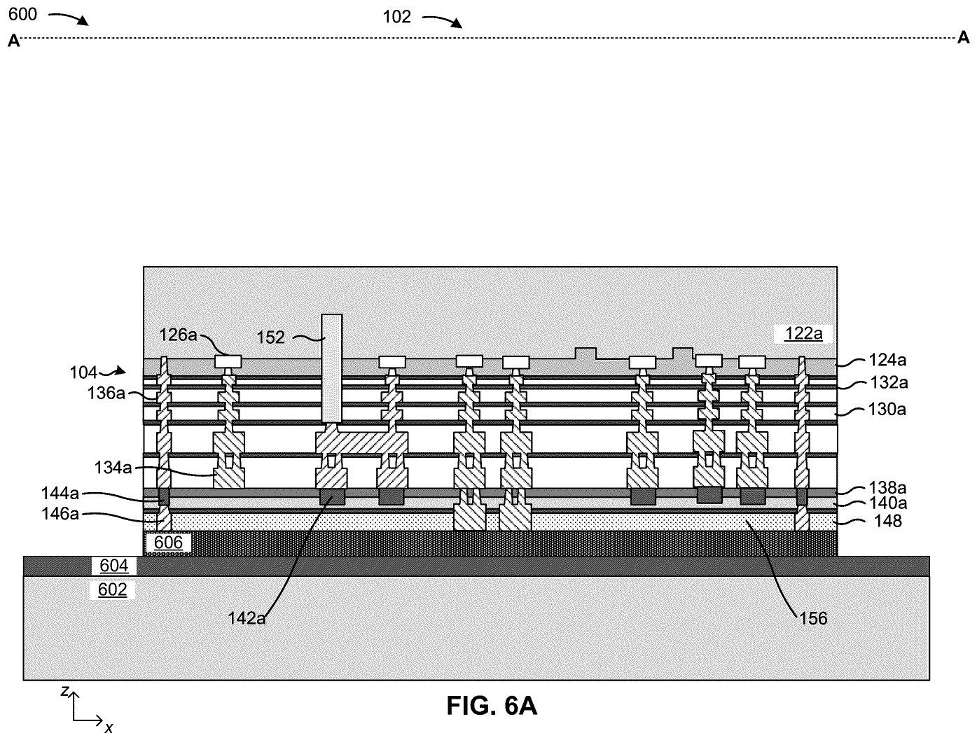

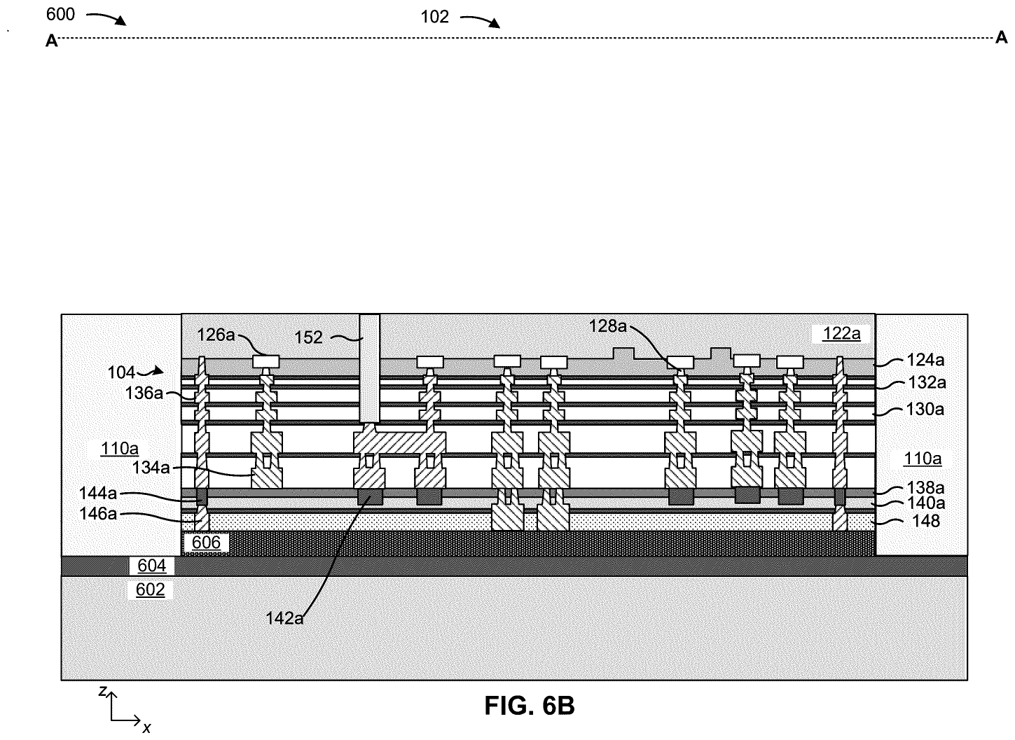

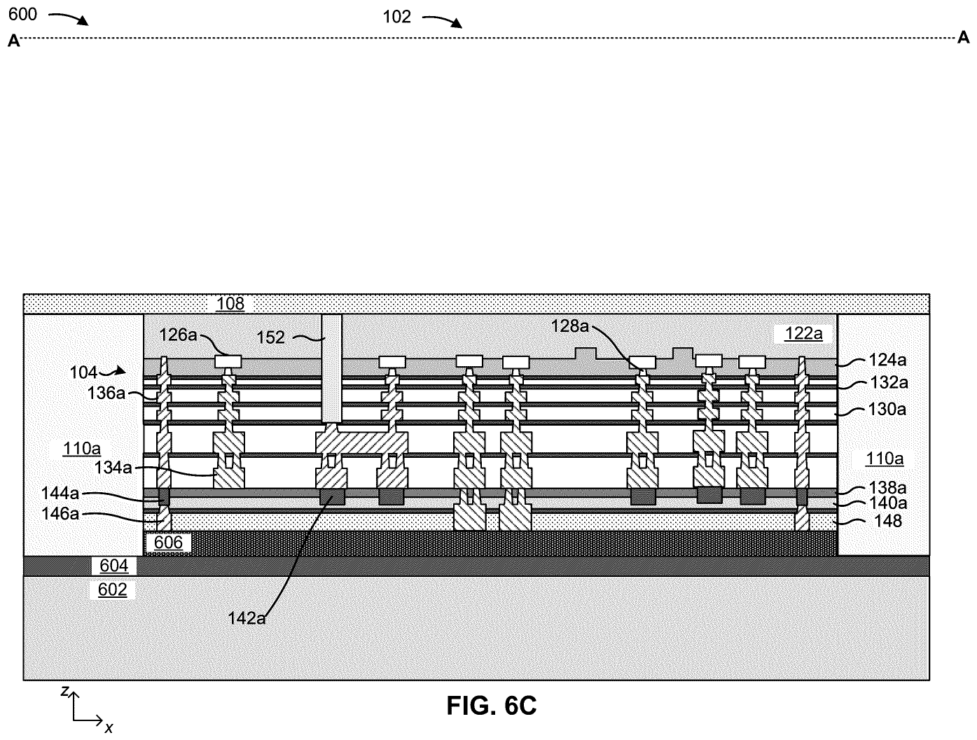

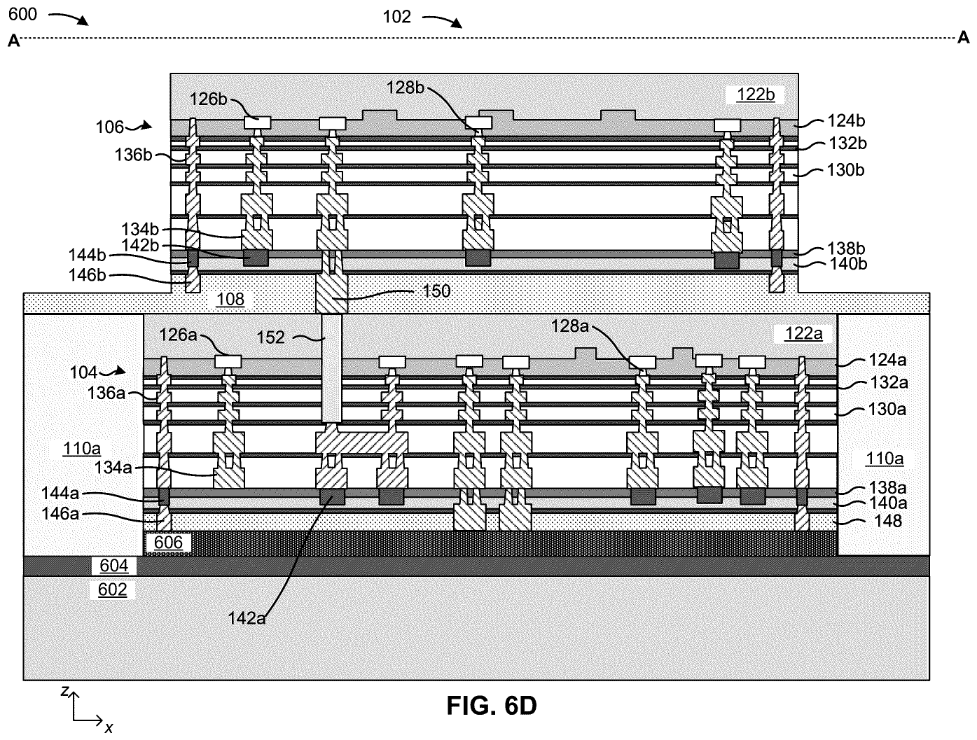

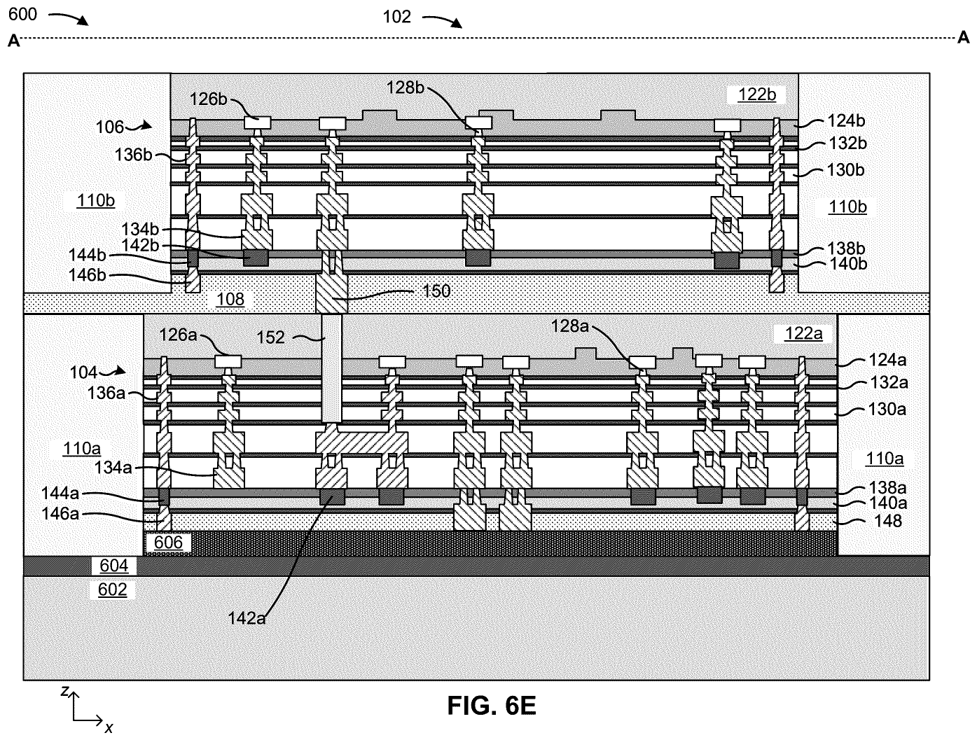

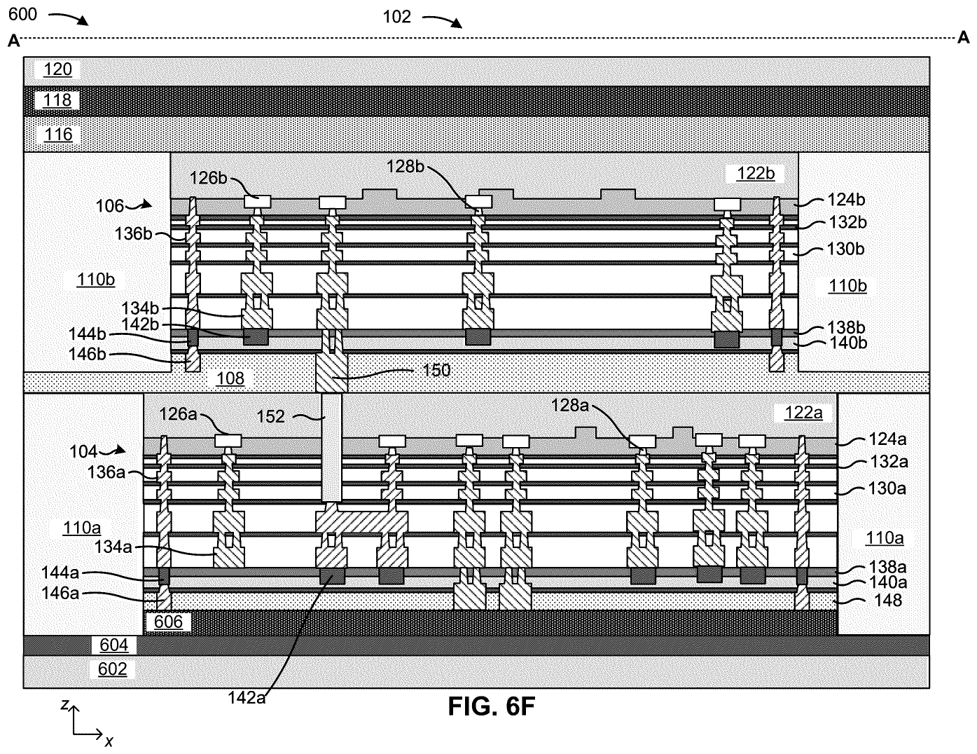

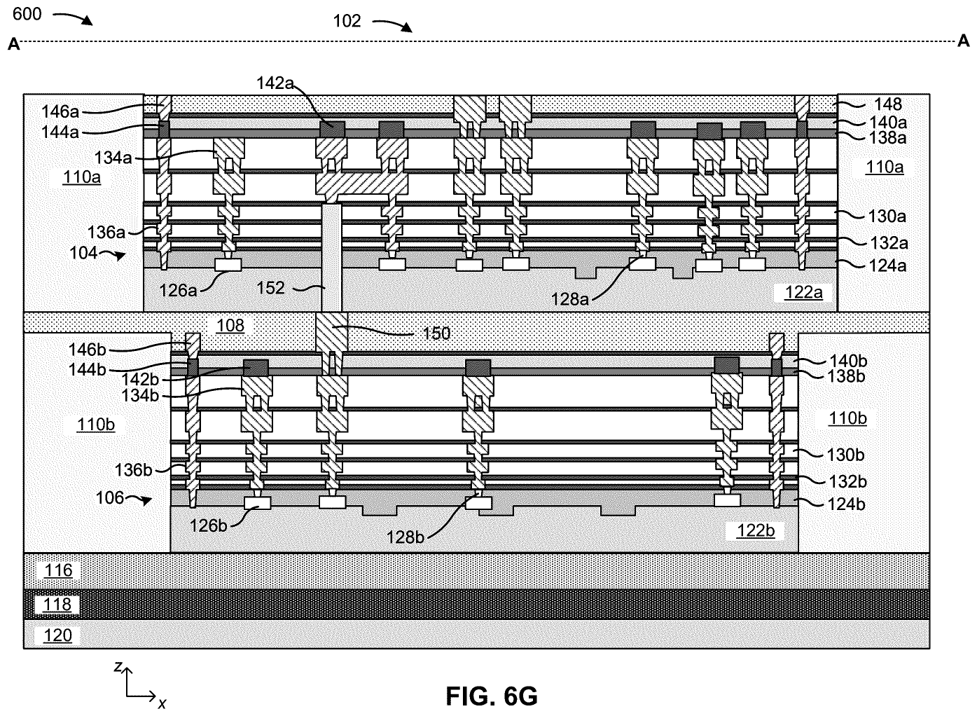

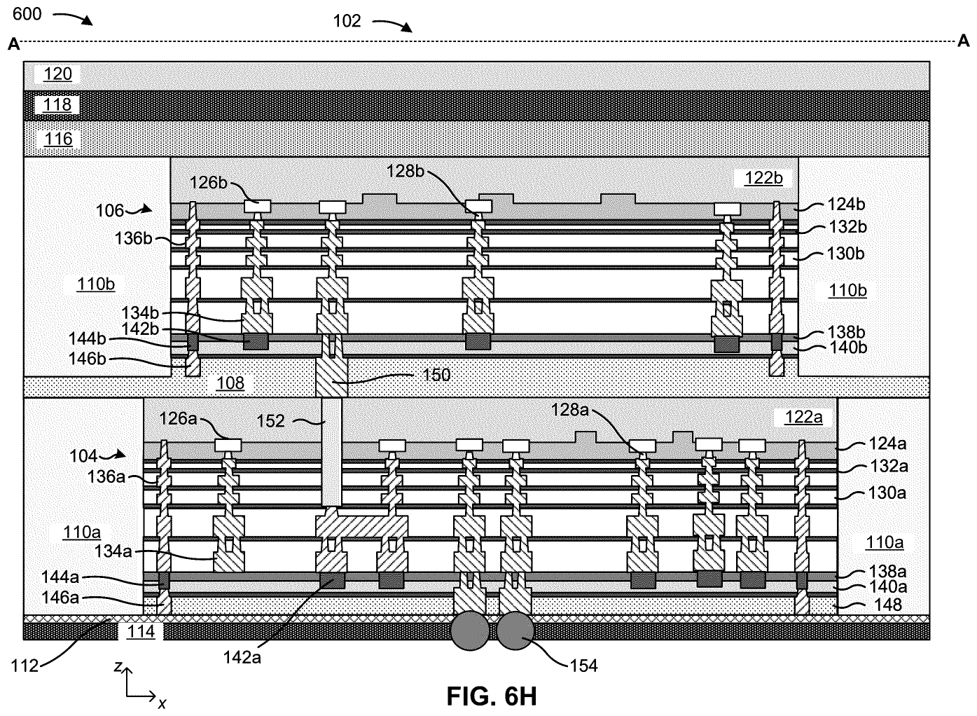

FIGS. 6A-6H are diagrams of an example implementation 600 of forming a portion of a semiconductor die package described herein. While the processing operations of the example implementation 600 are illustrated and described in connection with forming the semiconductor die package 102 described herein, the processing operations of the example implementation 600 may be performed to form another semiconductor device described herein, such as a semiconductor die package 702 of FIGS. 7A-7E, among other examples. In some implementations, one or more of the semiconductor processing operations described in connection with FIGS. 6A-6H may be performed using one or more semiconductor processing tools, such as a deposition tool, an exposure tool, a developer tool, an etch tool, a planarization tool, a bonding tool, a wafer/die transport tool, and/or another type of semiconductor processing tool.

As shown in FIG. 6A, the IC die 104 is bonded to a carrier substrate 602 using bonding layers 148, 604, and 606. Accordingly, the IC die 104 may be flipped or rotated 180 degrees to bond the IC die 104 to the carrier substrate 602. A bonding tool may be used to bond the IC die 104 to the carrier substrate 602 using a fusion bonding technique and/or another bonding technique. The bonding layers 604 and 606 may include fusion bonding layers or another type of bonding layers, and may be formed on the IC die 104 prior to bonding the IC die 104 to the carrier substrate 602, or may be included on the carrier substrate 602 prior to bonding the IC die 104 and the carrier substrate 602.

As shown in FIG. 6B, areas around the IC die 104 are filled with the dielectric fill layer 110a. A deposition tool may be used to deposit the dielectric fill layer 110a using a PVD technique, an ALD technique, a CVD technique, an oxidation technique, and/or another suitable deposition technique. The dielectric fill layer 110a may be deposited in one or more deposition operations.

As further shown in FIG. 6B, a planarization tool or wafer grinding tool may be used to perform a planarization operation (e.g., a CMP operation, a wafer grinding operation) to planarize the dielectric fill layer 110a and to remove material from the back side of the substrate 122a such that the die-to-die interconnect 152 is exposed through the back side of the substrate 122a.

As shown in FIG. 6C, the bonding layer 108 is formed over and/or on the back side of the substrate 122a of the IC die 104. A deposition tool may be used to deposit the bonding layer 108 using a PVD technique, an ALD technique, a CVD technique, an oxidation technique, and/or another suitable deposition technique. In some implementations, planarization tool is used to perform a planarization operation (e.g., a CMP operation,) to planarize the bonding layer 108.

As shown in FIG. 6D, the IC die 106 is bonded to the IC die 104 such that the IC die 104 and the IC die 106 are stacked and vertically arranged in the semiconductor die package 102. The IC die 106 may be formed using similar techniques and processes as those described in connection with FIGS. 3A-3E.

In some implementations, a bonding tool is used to bond the IC die 104 and the IC die 106 by forming dielectric-to-dielectric bonds between bonding layers 108 on each of the IC die 104 and the IC die 106. In some implementations, a bonding tool is used to bond the IC die 104 and the IC die 106 by forming metal-to-metal bonds between the die-to-die interconnect 152 of the IC die 104 and the bonding pads 150 of the IC die 106. In some implementations, a bonding tool is used to bond the IC die 104 and the IC die 106 by forming a combination of dielectric-to-dielectric bonds and metal-to-metal bonds.

As shown in FIG. 6E, areas around the IC die 106 are filled with the dielectric fill layer 110b such that the dielectric fill layer 110b surrounds the IC die 106. A deposition tool may be used to deposit the dielectric fill layer 110b using a PVD technique, an ALD technique, a CVD technique, an oxidation technique, and/or another suitable deposition technique. The dielectric fill layer 110b may be deposited in one or more deposition operations. A planarization tool may be used to perform a planarization operation (e.g., a CMP operation) to planarize the dielectric fill layer 110b and the substrate 122b of the IC die 106 such that the dielectric fill layer 110b and the substrate 122b of the IC die 106 are approximately co-planar.

As shown in FIG. 6F, the passivation layers 116-120 of the semiconductor die package 102 are formed or provided above the IC die 106. A deposition tool may be used to deposit the passivation layers 116-120 using a PVD technique, an ALD technique, a CVD technique, an oxidation technique, and/or another suitable deposition technique. The passivation layers 116-120 may be deposited in one or more deposition operations. In some implementations, a planarization tool may be used to perform a planarization operation (e.g., a CMP operation) to planarize the passivation layers 116-120 after the passivation layers 116-120 are deposited. Additionally and/or alternatively, one or more of the passivation layers 116-120 may be dispensed onto the IC die 106. Additionally and/or alternatively, the semiconductor die package 102 may be placed on one or more of the passivation layers 116-120 on a carrier substrate.

As shown in FIG. 6G, the semiconductor die package 102 is flipped and one or more operations are performed to remove the carrier substrate 602 and the bonding layers 604 and 606 from the semiconductor die package 102. In some implementations, the carrier substrate 602 is de-bonded from the semiconductor die package 102 by a thermal operation to alter the adhesive properties of the bonding layers 604 and/or 606. An energy source such as an ultraviolet (UV) laser, a carbon dioxide (CO₂) laser, or an infrared (IR) laser, among other examples, is utilized to irradiate and heat the bonding layers 604 and/or 606 until the adhesive properties of the bonding layer 604 and/or 606 are reduced. Then, the carrier substrate 602 and the bonding layers 604 and 606 are physically separated and removed from the semiconductor die package 102. Additionally and/or alternatively, the carrier substrate 602, the bonding layer 604, and/or the bonding layer 606 may be removed by etching and/or planarization.

As shown in FIG. 6H, the passivation layers 112 and 114 are formed on the IC die 104. A deposition tool may be used to deposit the passivation layers 112 and 114 using a PVD technique, an ALD technique, a CVD technique, an oxidation technique, and/or another suitable deposition technique. The passivation layers 112 and 114 may be deposited in one or more deposition operations. In some implementations, a planarization tool may be used to perform a planarization operation (e.g., a CMP operation) to planarize the passivation layers 112 and 114 after the passivation layers 112 and 114 are deposited. Additionally and/or alternatively, passivation layers 112 and/or 114 may be dispensed onto the IC die 104. The connection structures 154 may also be attached to the semiconductor die package 102.

As indicated above, FIGS. 6A-6H are provided as an example. Other examples may differ from what is described with regard to FIGS. 6A-6H.

FIGS. 7A-7E are diagrams of an example 700 of a semiconductor die package 702 described herein. The semiconductor die package 702 includes a packaged semiconductor device that includes a plurality of active IC dies or chips. The plurality of active IC dies may be vertically arranged and/or stacked in the semiconductor die package 702 using 3D packaging techniques such as direct bonding.

FIG. 7A illustrates a cross-section view of the semiconductor die package 702. As shown in FIG. 7A, the semiconductor die package 702 includes a similar combination and arrangement of layers and/or structures 704-754 as the layers and/or structures 104-154 of the semiconductor die package 102 illustrated and described in connection with FIG. 1A. The layers and/or structures 704-754 of the semiconductor die package 702 may be formed using similar techniques and/or processes to those described in connection with FIGS. 3A-3E, 4A-4G, 5A-5G, 6A-6H, and/or 8A-8C, among other examples.

However, as shown in FIG. 7A, the IC dies 704 and 706 are oriented in a mirrored configuration such that the interconnect layers of the IC dies 704 and 706 are facing each other. This enables the IC dies 704 and 706 to be directly bonded in a dielectric-to-dielectric bond between bonding layers 748 and 708, respectively, of the IC dies 704 and 706, and in metal-to-metal bonds between bonding pads 750a and 750b, respectively, of the IC dies 704 and 706.

FIGS. 7B and 7C illustrate detailed views of a portion 756 of the semiconductor die package 702 indicated in FIG. 7A. The portion 756 of the semiconductor die package 702 includes a portion in which a bonding structure 746a on a seal ring structure 736a of the IC die 704 is bonded with a bonding structure 746b on a seal ring structure 736b of the IC die 706. FIGS. 7D and 7E illustrate detailed views of a portion 758 of the of the semiconductor die package 702 indicated in FIG. 7A. The portion 758 of the semiconductor die package 702 includes a portion in which a bonding structure 746b on the seal ring structure 736b of the IC die 706 is not bonded with a bonding structure 746a on the seal ring structure 736a of the IC die 704, and is instead bonded with a bonding pad 750a of the IC die 704.

As shown in the detailed views of the portion 756 of the semiconductor die package 702 in FIGS. 7B and 7C, the IC die 704 may include a similar combination and arrangement of layers and/or structures 760-772 as the layers and/or structures 160-172 of the IC die 104, and the IC die 706 may include a similar combination and arrangement of layers and/or structures 774-786 as the layers and/or structures 174-186 of the IC die 106, as illustrated in the examples in FIGS. 1B-1E. However, and as shown in FIGS. 7B and 7C, the trench portion 768 (e.g., the bonding pad) of the bonding structure 746a of the IC die 704 is bonded to the trench portion 782 (e.g., the bonding pad) of the bonding structure 746b of the IC die 706 in a metal-to-metal bond. Moreover, the bonding layer 748 of the IC die 704 is bonded to the bonding layer 708 of the IC die 706 in a dielectric-to-dielectric bond. Thus, the IC dies 704 and 706 are bonded together in at least a portion of the respective seal ring regions of the IC dies 704 and 706 in a combination of metal-to-metal bonds and dielectric-to-dielectric bonds.

In the example in FIG. 7B, the via portion 766 of the bonding structure 746a extends into the opening 764 in the top portion 762 of the metal pad structure 744a, and the via portion 780 of the bonding structure 746b extends into the opening 778 in the top portion 776 of the metal pad structure 744b. In the example in FIG. 7C, the via portion 766 of the bonding structure 746a extends through the opening 764 in the top portion 762 of the metal pad structure 744a and into the bottom portion 760 of the metal pad structure 744a, and the via portion 780 of the bonding structure 746b extends through the opening 778 in the top portion 776 of the metal pad structure 744b and into the bottom portion 774 of the metal pad structure 744b.

As shown in the detailed views of the portion 758 of the semiconductor die package 702 in FIGS. 7D and 7E, a portion of the seal ring structure 736b of the IC die 706 may not be aligned with a portion of the seal ring structure 736a of the IC die 704. This may occur, for example, where the IC dies 704 and 706 are different sizes and/or different shapes. As a result, the trench portion 782 (e.g., the bonding pad) of a bonding structure 746b on a portion of the seal ring structure 736b may instead be aligned with, and bonded to, a bonding pad 750a in the IC die 704. The bonding pad 750a is not connected to the seal ring structure 736a of the IC die 704 or the metal pad structure 744a of the IC die 704. Thus, the portion of the seal ring structure 736b and the associated bonding structure 746b are not electrically connected with underlying IC devices 726a in the IC die 704.

In the example in FIG. 7D, the via portion 780 of the bonding structure 746b extends into the opening 778 in the top portion 776 of the metal pad structure 744b. In the example in FIG. 7E, the via portion 780 of the bonding structure 746b extends through the opening 778 in the top portion 776 of the metal pad structure 744b and into the bottom portion 774 of the metal pad structure 744b.

As indicated above, FIGS. 7A-7E are provided as an example. Other examples may differ from what is described with regard to FIGS. 7A-7E.

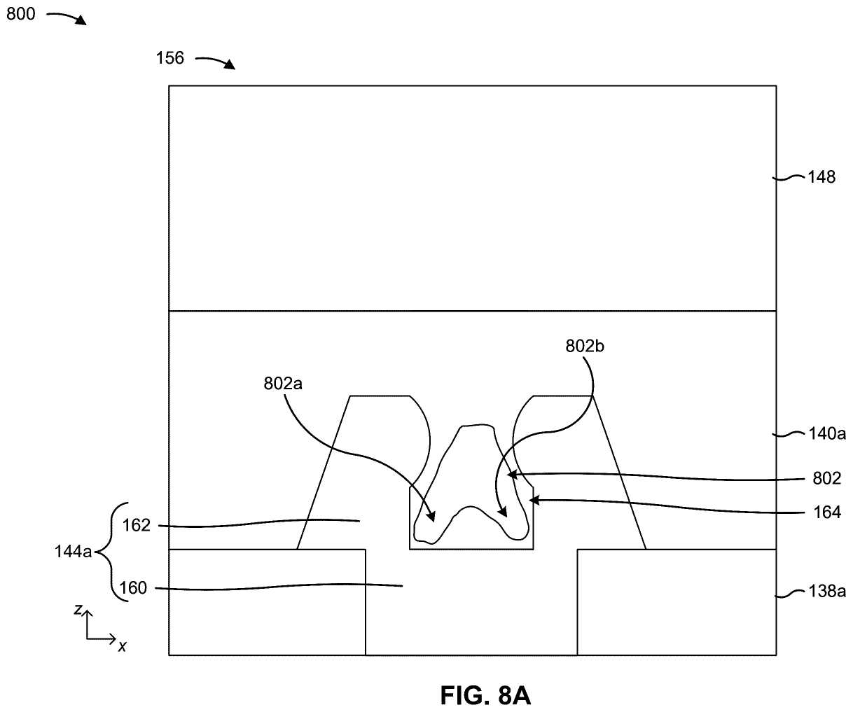

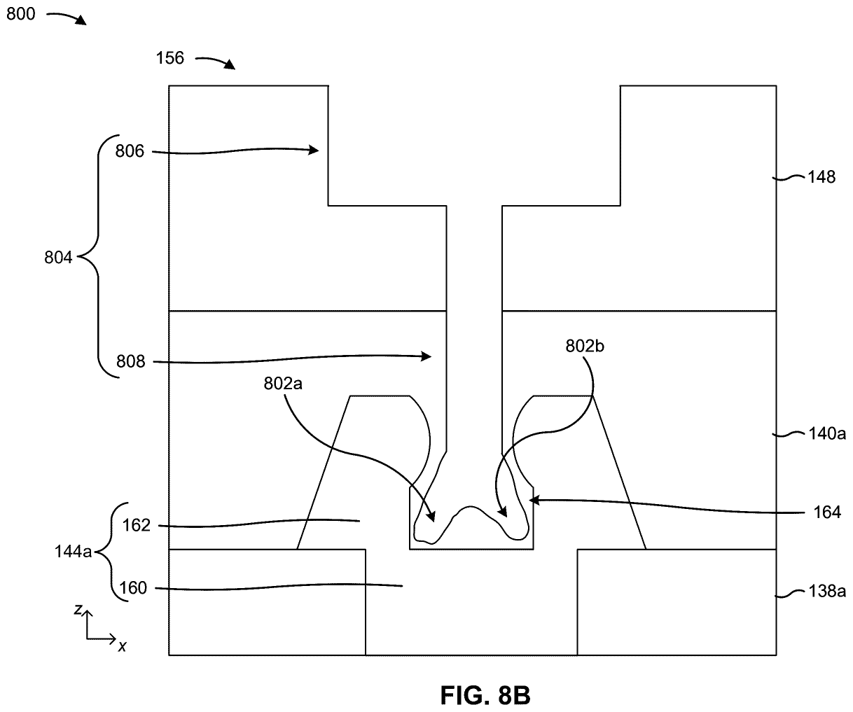

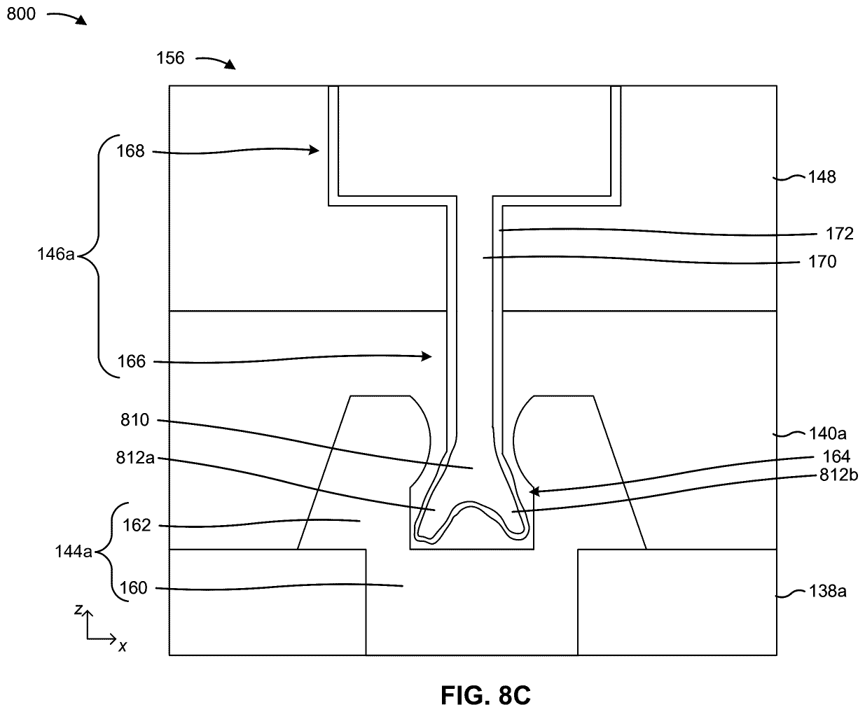

FIGS. 8A-8C are diagrams of an example implementation 800 of forming a portion of an IC die described herein. While the processing operations of the example implementation 800 are illustrated and described in connection with forming the semiconductor die package 102 described herein, the processing operations of the example implementation 800 may be performed to form another semiconductor device described herein, such as a semiconductor die package 702 of FIGS. 7A-7E, among other examples. In some implementations, one or more of the semiconductor processing operations described in connection with FIGS. 8A-8C may be performed using one or more semiconductor processing tools, such as a deposition tool, an exposure tool, a developer tool, an etch tool, a planarization tool, a wafer/die transport tool, and/or another type of semiconductor processing tool.

As shown in FIG. 8A, a metal pad structure 144a may be formed in a similar manner as described in connection with FIG. 4A, the passivation layer 140a may be formed in a similar manner as described in connection with FIG. 4B, and the bonding layer 148 may be formed in a similar manner as described in connection with FIG. 4B. However, the void 802 that forms in the passivation layer 140a within the opening 164 of the top portion 162 of the metal pad structure 144a may have a cross-sectional shape having extensions 802a and 802b at opposing sides of the void 802. The cross-sectional shape may occur due to the type of material used in the passivation layer 140a, the deposition rate for the material, the step coverage for the deposition technique used to deposit the passivation layer 140a, and/or another parameter associated with forming the passivation layer 140a.

As shown in FIG. 8B, a recess 804 is formed through the bonding layer 148 and into the passivation layer 140a in a similar manner as described above in connection with FIGS. 4C and 4D and/or in connection with FIGS. 5C and 5D. For example, a via-first process or a trench-first process may be performed to form a dual damascene recess that includes a trench portion 806 and a via portion 808 below the trench portion 806. The recess 804 is formed such that the via portion 808 extends through the opening 164 of the top portion 162 of the metal pad structure 144a and into the bottom portion 160 of the metal pad structure 144a and opens up the void 802, thereby exposing the extensions 802a and 802b.

As shown in FIG. 8C, the metal layer 170 and the liner 172 of the bonding structure 146a are formed in the recess 804 and then planarized in a similar manner as described in connection with FIGS. 4E-4G. The liner 172 conforms to the cross-sectional profile of the void 802, including the extensions 802a and 802b. Moreover, the metal layer 170 fills in the void 802, including the extensions 802a and 802b. Thus, the portion of the via portion 166 of the bonding structure 146a located in the opening 164 within the top portion 162 of the metal pad structure 144a includes a main portion 810 and extension portions 812a and 812b. The extension portions 812a and 812b respectively correspond to areas previously occupied by the extensions 802a and 802b of the void 802.

As indicated above, FIGS. 8A-8C are provided as an example. Other examples may differ from what is described with regard to FIGS. 8A-8C. In some implementations, the layers and/or structures of the IC die 106 (or a portion thereof) may be formed using similar processes and/or techniques as described in connection with FIGS. 8A-8C.

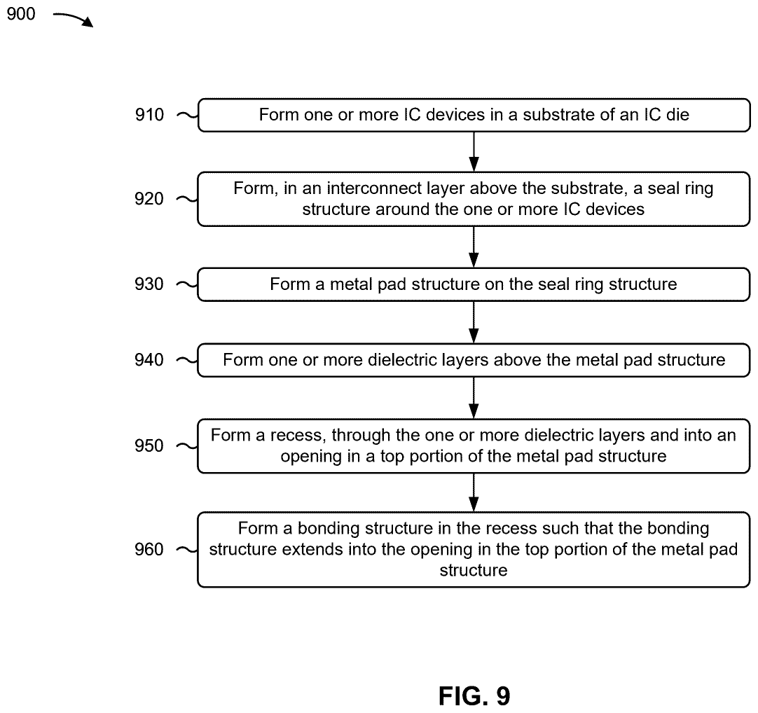

FIG. 9 is a flowchart of an example process 900 associated with forming a semiconductor die package described herein. In some implementations, one or more process blocks of FIG. 9 are performed using one or more semiconductor processing tools, such as a deposition tool, an exposure tool, a developer tool, an etch tool, a planarization tool, a bonding tool, an annealing tool, a wafer/die transport tool, and/or another type of semiconductor processing tool.

As shown in FIG. 9, process 900 may include forming one or more IC devices in a substrate of an IC die (block 910). For example, one or more semiconductor processing tools may be used to form one or more IC devices (e.g., IC devices 126a, IC devices 726a, IC devices 126b, IC devices 726b) in a substrate (e.g., a substrate 122a, a substrate 722a, a substrate 122b, a substrate 722b) of an IC die (e.g., an IC die 104, an IC die 704, an IC die 106, an IC die 706), as described herein.

As further shown in FIG. 9, process 900 may include forming, in an interconnect layer above the substrate, a seal ring structure around the one or more IC devices (block 920). For example, one or more semiconductor processing tools may be used to form, in an interconnect layer above the substrate, a seal ring structure (e.g., a seal ring structure 136a, a seal ring structure 736a, a seal ring structure 136b, a seal ring structure 736b) around the one or more IC devices, as described herein.

As further shown in FIG. 9, process 900 may include forming a metal pad structure on the seal ring structure (block 930). For example, one or more semiconductor processing tools may be used to form a metal pad structure (e.g., a metal pad structure 144a, a metal pad structure 744a, a metal pad structure 144b, a metal pad structure 744b) on the seal ring structure, as described herein.

As further shown in FIG. 9, process 900 may include forming one or more dielectric layers above the metal pad structure (block 940). For example, one or more semiconductor processing tools may be used to form one or more dielectric layers (e.g., a bonding layer 108, a passivation layer 140a, a passivation layer 140b a bonding layer 148, a bonding layer 708, a passivation layer 740a, a passivation layer 740b, a bonding layer 748) above the metal pad structure, as described herein.

As further shown in FIG. 9, process 900 may include forming a recess, through the one or more dielectric layers and into an opening in a top portion of the metal pad structure (block 950). For example, one or more semiconductor processing tools may be used to form a recess (e.g., a recess 404, a recess 804), through the one or more dielectric layers and into an opening in a top portion of the metal pad structure, as described herein.

As further shown in FIG. 9, process 900 may include forming a bonding structure in the recess such that the bonding structure extends into the opening in the top portion of the metal pad structure (block 960). For example, one or more semiconductor processing tools may be used to form a bonding structure (e.g., a bonding structure 146a, a bonding structure 746a, a bonding structure 146b, a bonding structure 746b) in the recess such that the bonding structure extends into the opening in the top portion of the metal pad structure, as described herein.

Process 900 may include additional implementations, such as any single implementation or any combination of implementations described below and/or in connection with one or more other processes described elsewhere herein.

In a first implementation, forming the recess includes forming the recess into a void (e.g., a void 402, a void 802) in the one or more dielectric layers that is located in the opening in the top portion of the metal pad structure to open the void, and forming the bonding structure includes filling the void with material of the bonding structure.

In a second implementation, alone or in combination with the first implementation, forming the bonding structure includes forming one or more liners (e.g., a liner 172, a liner 772) of the bonding structure in the recess, depositing a metal layer (e.g., a metal layer 170, a metal layer 770) on the one or more liners, and planarizing the one or more liners and the metal layer.

In a third implementation, alone or in combination with one or more of the first and second implementations, forming the recess includes forming a trench portion (e.g., a trench portion 406, a trench portion 806) of the recess, and forming a via portion (e.g., a via portion 408, a via portion 808) of the recess such that the via portion extends through the one or more dielectric layers and into the opening in the top portion of the metal pad structure.

In a fourth implementation, alone or in combination with one or more of the first through third implementations, forming the bonding structure comprises forming a via portion (e.g., a via portion 166, a via portion 766, a via portion 180, a via portion 780) of the bonding structure in the via portion of the recess such that the via portion of the bonding structure extends through the one or more dielectric layers and into the opening in the top portion of the metal pad structure, and forming a trench portion (e.g., a trench portion 168, a trench portion 768, a trench portion 182, a trench portion 782) of the bonding structure in the trench portion of the recess.

In a fifth implementation, alone or in combination with one or more of the first through fourth implementations, forming the bonding structure includes forming the bonding structure around the one or more IC devices such that the bonding structure includes a continuous structure that conforms to a top view layout of the seal ring structure.

In a sixth implementation, alone or in combination with one or more of the first through fifth implementations, forming the bonding structure comprises forming the bonding structure around the one or more IC devices such that the bonding structure includes a plurality of discontinuous segments that are arranged around a top view layout of the seal ring structure.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

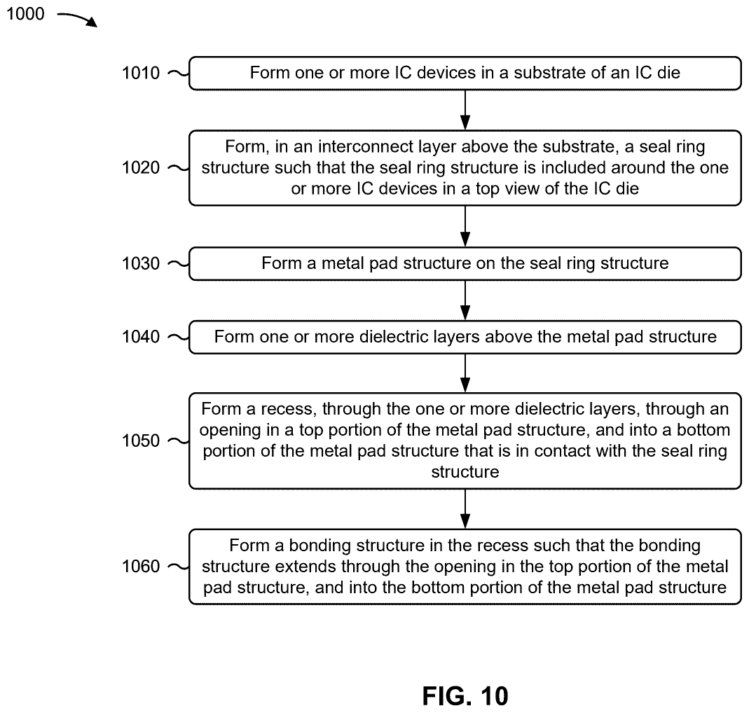

FIG. 10 is a flowchart of an example process 1000 associated with forming a semiconductor die package described herein. In some implementations, one or more process blocks of FIG. 10 are performed using one or more semiconductor processing tools, such as a deposition tool, an exposure tool, a developer tool, an etch tool, a planarization tool, a bonding tool, an annealing tool, a wafer/die transport tool, and/or another type of semiconductor processing tool.

As shown in FIG. 10, process 1000 may include forming one or more IC devices in a substrate of an IC die (block 1010). For example, one or more semiconductor processing tools may be used to form one or more IC devices (e.g., IC devices 126a, IC devices 726a, IC devices 126b, IC devices 726b) in a substrate (e.g., a substrate 122a, a substrate 722a, a substrate 122b, a substrate 722b) of an IC die (e.g., an IC die 104, an IC die 704, an IC die 106, an IC die 706), as described herein.

As further shown in FIG. 10, process 1000 may include forming, in an interconnect layer above the substrate, a seal ring structure such that the seal ring structure is included around the one or more IC devices in a top view of the IC die (block 1020). For example, one or more semiconductor processing tools may be used to form, in an interconnect layer above the substrate, a seal ring structure (e.g., a seal ring structure 136a, a seal ring structure 736a, a seal ring structure 136b, a seal ring structure 736b) such that the seal ring structure is included around the one or more IC devices in a top view of the IC die, as described herein.

As further shown in FIG. 10, process 1000 may include forming a metal pad structure on the seal ring structure (block 1030). For example, one or more semiconductor processing tools may be used to form a metal pad structure (e.g., a metal pad structure 144a, a metal pad structure 744a, a metal pad structure 144b, a metal pad structure 744b) on the seal ring structure, as described herein.

As further shown in FIG. 10, process 1000 may include forming one or more dielectric layers above the metal pad structure (block 1040). For example, one or more semiconductor processing tools may be used to form one or more dielectric layers (e.g., a bonding layer 108, a passivation layer 140a, a passivation layer 140b a bonding layer 148, a passivation layer 740a, 740b, a bonding layer 708, a bonding layer 748) above the metal pad structure, as described herein.

As further shown in FIG. 10, process 1000 may include forming a recess, through the one or more dielectric layers, through an opening in a top portion of the metal pad structure, and into a bottom portion of the metal pad structure that is in contact with the seal ring structure (block 1050). For example, one or more semiconductor processing tools may be used to form a recess (e.g., a recess 404), through the one or more dielectric layers, through an opening (e.g., an opening 164, an opening 178, an opening 764, an opening 778) in a top portion (e.g., a top portion 162, a top portion 176, a top portion 762, a top portion 776) of the metal pad structure, and into a bottom portion (e.g., a bottom portion 160, a bottom portion 174, a bottom portion 760, a bottom portion 774) of the metal pad structure that is in contact with the seal ring structure, as described herein.

As further shown in FIG. 10, process 1000 may include forming a bonding structure in the recess such that the bonding structure extends through the opening in the top portion of the metal pad structure, and into the bottom portion of the metal pad structure (block 1060). For example, one or more semiconductor processing tools may be used to form a bonding structure (e.g., a bonding structure 146a, a bonding structure 746a, a bonding structure 146b, a bonding structure 746b) in the recess such that the bonding structure extends through the opening in the top portion of the metal pad structure, and into the bottom portion of the metal pad structure, as described herein.

Process 1000 may include additional implementations, such as any single implementation or any combination of implementations described below and/or in connection with one or more other processes described elsewhere herein.

In a first implementation, the metal pad structure includes aluminum (Al) or aluminum copper (AlCu), and the bonding structure includes copper (Cu).

In a second implementation, alone or in combination with the first implementation, forming the bonding structure includes forming a liner (e.g., a liner 172, a liner 772) of the bonding structure in the recess such the liner is in contact with the bottom portion of the metal pad structure, depositing a metal layer (e.g., a metal layer 170, a metal layer 770) on the liner such that the liner is between the metal pad structure and the metal layer, and planarizing the liner and the metal layer.

In a third implementation, alone or in combination with one or more of the first and second implementations, forming the recess includes forming a plurality of recesses through the one or more dielectric layers, through the opening in the top portion of the metal pad structure, and into the bottom portion of the metal pad structure, and forming the bonding structure includes forming a segment of the bonding structure in each of the plurality of recesses.

In a fourth implementation, alone or in combination with one or more of the first through third implementations, process 1000 includes bonding the IC die with another IC die (e.g., an IC die 704, an IC die 706) such that the bonding structure is bonded with another bonding structure above another seal ring structure of the other IC die.

In a fifth implementation, alone or in combination with one or more of the first through fourth implementations, forming the metal pad structure includes forming a plurality of discontinuous segments of the metal pad structure, forming the recess includes forming a plurality of recesses through the one or more dielectric layers, through openings in top portions of the plurality of discontinuous segments of the metal pad structure, and into bottom portions of the plurality of discontinuous segments of the metal pad structure, and forming the bonding structure includes forming a segment of the bonding structure in each of the plurality of recesses.

In a sixth implementation, alone or in combination with one or more of the first through fifth implementations, forming the recess includes forming a trench portion (e.g., a trench portion 406) of the recess in a first dielectric layer (e.g., a bonding layer 108, a bonding layer 148, a bonding layer 708, a bonding layer 748) of the one or more dielectric layers, and forming a via portion (e.g., a via portion 408) of the recess in a second dielectric layer (140a, 140b, 740a, 740b), of the one or more dielectric layers, below the first dielectric layer such that the via portion extends through the opening in the top portion of the metal pad structure, and into the bottom portion of the metal pad structure.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, a recess is formed through a passivation layer of an IC die and into an opening in a metal pad structure at the top of a seal ring structure of the IC die. The recess is formed to open up any voids that may have occurred in the passivation layer within the opening in the metal pad structure. This enables the recess (and thus, the void) to be filled in, which reduces the likelihood that the void might otherwise cause delamination and film peeling in the passivation layer. The recess (and thus, the void) may be filled in to form a bonding via and a bonding pad, which may be dummy structures or may be used to bond the IC die with another IC in the semiconductor die package. In this way, opening up the void and filling in the void may increase the reliability of the semiconductor die package, and may decrease the likelihood of die-to-die debonding and failure in the semiconductor die package, among other examples.

Moreover, the process for filling in the void can be integrated into the overall bonding via/pad process for the IC die, thereby minimizing the complexity, cost, and time impact of filling in the voids.

As described in greater detail above, some implementations described herein provide a method. The method includes forming one or more IC devices in a substrate of an IC die. The method includes forming, in an interconnect layer above the substrate, a seal ring structure around the one or more IC devices. The method includes forming a metal pad structure on the seal ring structure. The method includes forming one or more dielectric layers above the metal pad structure. The method includes forming a recess, through the one or more dielectric layers and into an opening in a top portion of the metal pad structure. The method includes forming a bonding structure in the recess such that the bonding structure extends into the opening in the top portion of the metal pad structure.

As described in greater detail above, some implementations described herein provide a method. The method includes forming one or more IC devices in a substrate of an IC die. The method includes forming, in an interconnect layer above the substrate, a seal ring structure such that the seal ring structure is included around the one or more IC devices in a top view of the IC die. The method includes forming a metal pad structure on the seal ring structure. The method includes forming one or more dielectric layers above the metal pad structure. The method includes forming a recess, through the one or more dielectric layers, through an opening in a top portion of the metal pad structure, and into a bottom portion of the metal pad structure that is in contact with the seal ring structure. The method includes forming a bonding structure in the recess such that the bonding structure extends through the opening in the top portion of the metal pad structure, and into the bottom portion of the metal pad structure.

As described in greater detail above, some implementations described herein provide a semiconductor die package. The semiconductor die package includes a first IC die. The semiconductor die package includes a second IC die vertically arranged with the first IC die in the semiconductor die package. The first IC die includes a seal ring structure laterally surrounding a perimeter of the first IC die. The first IC die includes a first metal pad structure on the seal ring structure, where the first metal pad structure includes an opening in a top portion of the first metal pad structure. The first IC die includes a second metal pad structure on the first metal pad structure, where a via portion of the second metal pad structure extends into the opening in the top portion of the first metal pad structure.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming one or more integrated circuit (IC) devices in a substrate of an IC die;
forming, in an interconnect layer above the substrate, a seal ring structure around the one or more IC devices;
forming a metal pad structure on the seal ring structure;
forming one or more dielectric layers above the metal pad structure;
forming a recess, through the one or more dielectric layers and into an opening in a top portion of the metal pad structure; and
forming a bonding structure in the recess such that the bonding structure extends into the opening in the top portion of the metal pad structure.

2. The method of claim 1, wherein forming the recess comprises forming the recess into a void in the one or more dielectric layers that is located in the opening in the top portion of the metal pad structure to open the void; and
wherein forming the bonding structure comprises filling the void with material of the bonding structure.

3. The method of claim 1, wherein forming the bonding structure comprises:
forming one or more liners of the bonding structure in the recess;
depositing a metal layer on the one or more liners; and
planarizing the one or more liners and the metal layer.

4. The method of claim 1, wherein forming the recess comprises:
forming a trench portion of the recess; and
forming a via portion of the recess such that the via portion extends through the one or more dielectric layers and into the opening in the top portion of the metal pad structure.

5. The method of claim 4, wherein forming the bonding structure comprises:
forming a via portion of the bonding structure in the via portion of the recess such that the via portion of the bonding structure extends through the one or more dielectric layers and into the opening in the top portion of the metal pad structure; and
forming a trench portion of the bonding structure in the trench portion of the recess.

6. The method of claim 1, wherein forming the bonding structure comprises forming the bonding structure around the one or more IC devices such that the bonding structure comprises a continuous structure that conforms to a top view layout of the seal ring structure.

7. The method of claim 1, wherein forming the bonding structure comprises forming the bonding structure around the one or more IC devices such that the bonding structure comprises a plurality of discontinuous segments that are arranged around a top view layout of the seal ring structure.

8. A method, comprising:
forming one or more integrated circuit (IC) devices in a substrate of an IC die;
forming, in an interconnect layer above the substrate, a seal ring structure such that the seal ring structure is included around the one or more IC devices in a top view of the IC die;
forming a metal pad structure on the seal ring structure;
forming one or more dielectric layers above the metal pad structure;
forming a recess, through the one or more dielectric layers, through an opening in a top portion of the metal pad structure, and into a bottom portion of the metal pad structure that is in contact with the seal ring structure; and
forming a bonding structure in the recess such that the bonding structure extends through the opening in the top portion of the metal pad structure, and into the bottom portion of the metal pad structure.

9. The method of claim 8, wherein the metal pad structure comprises aluminum (Al) or aluminum copper (AlCu); and
wherein the bonding structure comprises copper (Cu).

10. The method of claim 8, wherein forming the bonding structure comprises:
forming a liner of the bonding structure in the recess such the liner is in contact with the bottom portion of the metal pad structure;
depositing a metal layer on the liner such that the liner is between the metal pad structure and the metal layer; and
planarizing the liner and the metal layer.

11. The method of claim 8, wherein forming the recess comprises forming a plurality of recesses through the one or more dielectric layers, through the opening in the top portion of the metal pad structure, and into the bottom portion of the metal pad structure; and
wherein forming the bonding structure comprises forming a segment of the bonding structure in each of the plurality of recesses.

12. The method of claim 8, further comprising:
bonding the IC die with another IC die such that the bonding structure is bonded with another bonding structure above another seal ring structure of the other IC die.

13. The method of claim 8, wherein forming the metal pad structure comprises forming a plurality of discontinuous segments of the metal pad structure;
wherein forming the recess comprises forming a plurality of recesses through the one or more dielectric layers, through openings in top portions of the plurality of discontinuous segments of the metal pad structure, and into bottom portions of the plurality of discontinuous segments of the metal pad structure; and
wherein forming the bonding structure comprises forming a segment of the bonding structure in each of the plurality of recesses.

14. The method of claim 8, wherein forming the recess comprises:
forming a trench portion of the recess in a first dielectric layer of the one or more dielectric layers; and
forming a via portion of the recess in a second dielectric layer, of the one or more dielectric layers, below the first dielectric layer such that the via portion extends through the opening in the top portion of the metal pad structure, and into the bottom portion of the metal pad structure.

15. A package, comprising:
a first integrated circuit (IC) die; and
a second IC die on vertically arranged with the first IC die in the semiconductor die package,
wherein the first IC die comprises:
a seal ring structure laterally surrounding the first IC die;
a first metal pad structure on the seal ring structure,
wherein the first metal pad structure comprises an opening in a top portion of the first metal pad structure; and
a second metal pad structure on the first metal pad structure,
wherein a via portion of the second metal pad structure extends into the opening in the top portion of the first metal pad structure.

16. The semiconductor die package of claim 15, wherein the second IC die comprises:
another seal ring structure laterally surrounding of the second IC die; and
a third metal pad structure between the other seal ring structure and the second metal pad structure,
wherein the third metal pad structure is bonded to the second metal pad structure.

17. The semiconductor die package of claim 16 wherein the second IC die further comprises a fourth metal pad structure on the other seal ring structure; and
wherein the third metal pad structure is coupled to the fourth metal pad structure.

18. The semiconductor die package of claim 17, wherein the fourth metal pad structure comprises an opening in a top portion of the third metal pad structure; and
wherein a via portion of the third metal pad structure extends into the opening in the top portion of the fourth metal pad structure.

19. The semiconductor die package of claim 16, wherein one or more dielectric layers in the second IC die are included between the other seal ring structure and the third metal pad structure.

20. The semiconductor die package of claim 15, wherein the first IC die comprises a bonding pad within a perimeter of the seal ring structure; and
wherein the second IC die comprises:
another seal ring structure laterally surrounding of the second IC die; and
a third metal pad structure between the other seal ring structure and the bonding pad,
wherein the third metal pad structure is bonded to the bonding pad.
